(19) United States
(12) Patent Application Publication
(10) Pub. No.: US 2025/0107108 A1
(43) Pub. Date: Mar. 27, 2025

(54) MEMORY LAYERS BONDED TO LOGIC LAYERS WITH INCLINATION

(71) Applicant: Intel Corporation, Santa Clara, CA (US)

(72) Inventors: Abhishek A. Sharma, Portland, OR (US); Sagar Suthram, Portland, OR (US); Wilfred Gomes, Portland, OR (US); Tahir Ghani, Portland, OR (US); Anand S. Murthy, Portland, OR (US); Pushkar Sharad Ranade, San Jose, CA (US)

(73) Assignee: Intel Corporation, Santa Clara, CA (US)

(21) Appl. No.: 18/473,421

(22) Filed: Sep. 25, 2023

(51) Int. Cl. H10B 80/00; H01L 23/00; H01L 25/065; H01L 25/18

(52) U.S. Cl. CPC H10B 80/00; H01L 24/08; H01L 25/0652; H01L 25/18; H01L 2224/08145; H01L 2924/1431; H01L 2924/1436; H01L 2924/1437

(57) ABSTRACT

An IC device may include memory layers bonded to a logic layer with inclination. An angle between a memory layer and the logic layer may be in a range from approximately 0 to approximately 90 degrees. The memory layers may be over the logic layer. The IC device may include one or more additional logic layers that are parallel to a memory layer or perpendicular to a memory layer. The one or more additional logic layers may be over the logic layer. A memory layer may include memory cells. The logic layer may include logic circuits (e.g., sense amplifier, word line driver, etc.) that control the memory cells. Bit lines (or word lines) in different memory layers may be coupled to each other. A bit line and a word line in a memory layer may be controlled by logic circuits in different logic layers.

### BACKGROUND

Integrated circuit (IC) fabrication usually includes two stages. The first stage is referred to as the front end of line (FEOL). The second stage is referred to as the back end of line (BEOL). In the FEOL, individual semiconductor devices components (e.g., transistor, capacitors, resistors, etc.) can be patterned on a wafer. The FEOL stage may include a complementary metal-oxide-semiconductor (CMOS) process, in which metal-oxide-semiconductor field-effect transistors (MOSFETs) (such as symmetrical pairs of P-type and N-type MOSFETs) can be fabricated. In the BEOL, metal layers, vias, and insulating layers can be formed to get the individual components interconnected. The BEOL usually starts with forming the first metal layer on the wafer. The first metal layer is often called M0.More metal layers can be formed on top of M0, and these metal layers are often called M1, M2, and so on.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1C illustrate IC devices including memory layers bonded to logic layers with orthogonal inclination, according to some embodiments of the disclosure.

FIGS. 2A and 2B illustrate IC devices including memory layers bonded to logic layers with non-orthogonal inclination, according to some embodiments of the disclosure.

FIG. 3 illustrates an IC device including memory layers with global word lines, according to some embodiments of the disclosure.

FIG. 4 illustrates an IC device with transistors having global gate electrodes, according to some embodiments of the disclosure.

FIG. 5 illustrates an IC device with transistors having global source or drain electrodes, according to some embodiments of the disclosure.

FIG. 6 illustrates a logic layer with a power interconnect and a signal interconnect, according to some embodiments of the disclosure.

FIG. 7 illustrates a memory layer, according to some embodiments of the disclosure.

FIG. 8 shows a transistor with a fin, according to some embodiments of the disclosure.

FIG. 9 shows a transistor with nanoribbons, according to some embodiments of the disclosure.

FIG. 10A illustrates semiconductor regions of a transistor in a memory die, according to some embodiments of the disclosure.

FIG. 10B illustrates semiconductor regions of a transistor in a logic die, according to some embodiments of the disclosure.

FIG. 11 is an electric circuit diagram of an example dynamic random-access memory (DRAM) array, according to some embodiments of the present disclosure.

FIG. 12A is an electric circuit diagram of an example static random-access memory (SRAM) cell, according to some embodiments of the present disclosure.

FIG. 12B provides a top-down plan view of an example implementation of the SRAM cell, according to some embodiments of the present disclosure.

FIGS. 13A and 13B are top views of a wafer and dies that can facilitate memory layers bonded to one or more logic layers with inclination, according to some embodiments of the disclosure.

FIG. 14 is a side, cross-sectional view of an example IC package that may include memory layers bonded to one or more logic layers with inclination, according to some embodiments of the disclosure.

FIG. 15 is a cross-sectional side view of an IC device assembly that may include components having memory layers bonded to one or more logic layers with inclination, according to some embodiments of the disclosure.

FIG. 16 is a block diagram of an example computing device that may include one or more components with memory layers bonded to one or more logic layers with inclination, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Embodiments of the present disclosure are applicable to different types of memory devices. Some embodiments of the present disclosure may refer to SRAM. Other embodiments of the present disclosure may refer to DRAM. However, embodiments of the present disclosure may be equally applicable to memory cells implemented other technologies. Thus, in general, memory cells/arrays described herein may be implemented as standalone SRAM devices, DRAM devices, or any other volatile or nonvolatile memory cells/arrays.

A memory cell is a fundamental building block of computer memory devices used to store and retrieve data. It is a small unit of storage that can hold a single bit of information, which can be either a 0 or a 1. Memory cells are organized in a grid-like structure to form memory arrays. A memory cell usually includes a memory element, which stores information, and an access transistor, which is coupled to the memory element and controls access to the memory element. A memory device also includes bit lines and word lines coupled to memory cells. A bit line can couple the memory cells in the memory array to the memory control circuitry. A bit line can be used for reading and writing data. A word line can be used to control the access to a specific row of memory cells in the memory array. When the word line is activated, it enables the data stored in the selected row to be read or modified.

Many currently available memory devices usually have logic circuits in memory layers. A memory layer may be a memory die or a memory wafer that can be partitioned into a number of individual memory dies. Logic circuits in memory layers may be peripheral circuits, such as sense amplifiers, decoders, and so on. Fabrication of memory layers implemented with logic circuits typically requires CMOS processes. However, CMOS processes are not always cost efficient. The cost of manufacturing these memory layers can be high.

Some other memory devices have memory layers stacked over logic layers and have control circuits arranged in the logic layers. The cost of manufacturing the memory layers can be lower. A logic layer may be a logic die or a logic wafer that can be partitioned into a number of individual layer dies. Memory dies and logic dies may be collectively referred to as IC dies. IC dies can stacked in various ways: including (1) back-to-back, in which the substrate of one IC die is in direct contact with the substrate of another IC die; (2) back-to-front, in which the substrate of one IC die is in direct contact with the metallization stack of the other IC die; and (3) front-to-front, in which the metallization stacks of the two IC dies are in direct contact. In all these configurations, the dies are usually parallel to each other, e.g., with the active circuitry disposed in planes parallel to the contacting areas of adjacent dies. Such architecture suffers from certain inherent limitations. For example, such placement can limit the number of IC dies that can be placed in a package with a limited (or constrained) footprint. Also, logic dies typically include high-performance compute circuitry that can generate a significant amount of heat during operation, which limits where logic dies can be placed without causing overheating problems.

Embodiments of the present disclosure may improve on at least some of the challenges and issues described above by providing memory layers bonded to logic layers with inclination. In an example, memory layers may be arranged over a logic layer and at an angle from a logic layer. The angle may be approximately 0 degrees to approximately 90 degrees. The memory layers may be in parallel with each other. One or more additional logic layers may be placed over the logic layer. An additional logic layer may be parallel or perpendicular to a memory layer. The logic layer(s) can provide control circuits that control operations of the memory layers. Examples of the control circuits may include sense amplifiers, word line drivers, decoders, buffers, and so on.

In various embodiments of the present disclosure, an IC device (which may also be referred to as an IC assembly) may include one or more memory layers over a logic layer. In some embodiments, each memory layer may be bonded to the logic layer orthogonally, i.e., the angle between the memory layer and the logic layer is approximately 90 degrees. In other embodiments, the angle between a memory layer and the logic layer may be different, such as 10 degrees, 30degrees, 50 degrees, 70 degrees, and so on. The logic layer may include logic circuits that can control operations of the memory layers. For instance, the logic layer may include sense amplifiers coupled to bit lines in the memory layer, word line drivers coupled to word lines in the memory layers, or other types of circuits. Bit lines in different memory layers may be electrically coupled. For instance, these bit lines may be connected through one or more conductive structures arranged over the logic die or through electrodes of transistors in the memory layers. The coupled bit lines are referred to as “global bit lines” and can be controlled globally, e.g., by using the same sense amplifier. Additionally or alternatively, word lines in some memory layers may be electrically coupled. The coupled word lines are referred to as “global word lines” and can be controlled globally, e.g., by using the same word line driver.

The logic layer may be a first logic layer in the IC device, and the IC device may include one or more other logic layers, such as a second logic layer, a third logic layer, and so on. In an example, a second logic layer may be placed between two memory layers. In another example, a second logic layer may be placed over the first logic layer in a way that it is orthogonal to the memory layers. The second logic layer may include one or more circuits different from the circuits in the first logic layer. For instance, the first logic layer may include one or more sense amplifiers, while the second logic layer may include one or more write line drivers; or the first logic layer may include one or more write line drivers, while the second logic layer may include one or more sense amplifiers.

A memory layer or logic layer in the IC device may include one or more transistors. Transistors in different layers may be different. In an embodiment, a logic layer may include transistors pairs, each transistor pair having a P-type metal-oxide-semiconductor (PMOS) transistor and a N-type metal-oxide-semiconductor (NMOS) transistor; while a memory layer may include either PMOS transistors or NMOS transistors. In another embodiment, semiconductor structures of transistors in different layers can be different. For instance, a semiconductor structure of a transistor in a logic layer may be a nanoribbon, versus a semiconductor structure of a transistor in another logic layer or in a memory layer may be a fin. In yet another embodiment, two semiconductor structures of transistors in two layers may both have nanoribbons, but the sizes of the nanoribbons may be different.

The present disclosure provides IC devices in which memory layers are bonded to logic layers with inclination. The cost for fabricating such IC devices can be reduced by placing logic circuits in the logic layers to avoid CMOS processes for fabricating memory layers. Also, due to the different orientations of the memory layers from the logic layer, dissipation of heat generated by the logic layer can be more efficient. Moreover, compared with currently available technologies, the present disclosure provides more flexibility in terms of packing IC dies. Various numbers (e.g., from two to a thousand) of memory dies can be packed and bonded to the same logic layer. Memory bandwidth can be enhanced.

It should be noted that, in some settings, the term “nanoribbon” has been used to describe an elongated semiconductor structure that has a substantially rectangular transverse cross section (e.g., a cross section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the term “or” refers to an inclusive “or” and not to an exclusive “or.” The phrase “A and/or B” or the phase “A or B” means (A), (B), or (A and B). For the purposes of the present disclosure, the phrase “A, B, and/or C” or the phase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

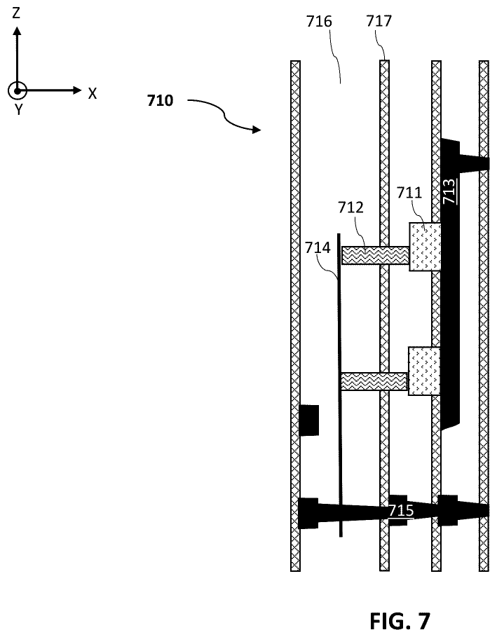

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross section of a device to detect the shape and the location of various device elements described herein using e.g., Physical Failure Analysis (PFA) would allow determination of presence of memory layers bonded to one or more logic layers with inclination as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various memory layers bonded to one or more logic layers with inclination as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

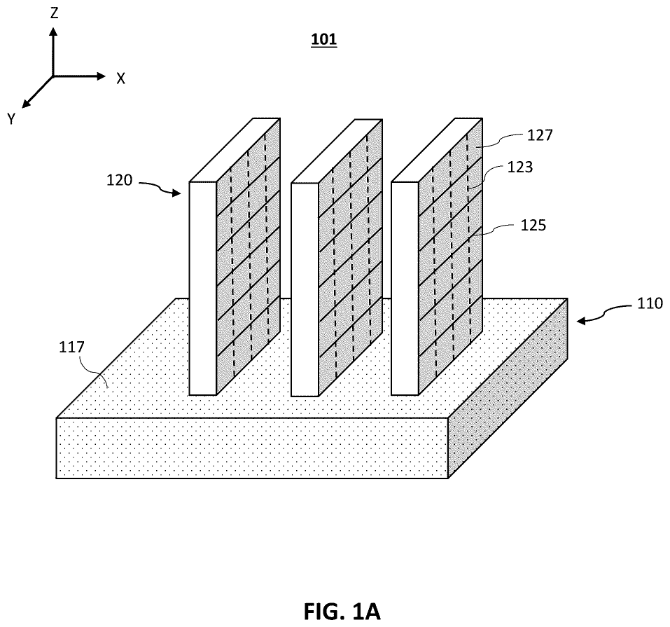

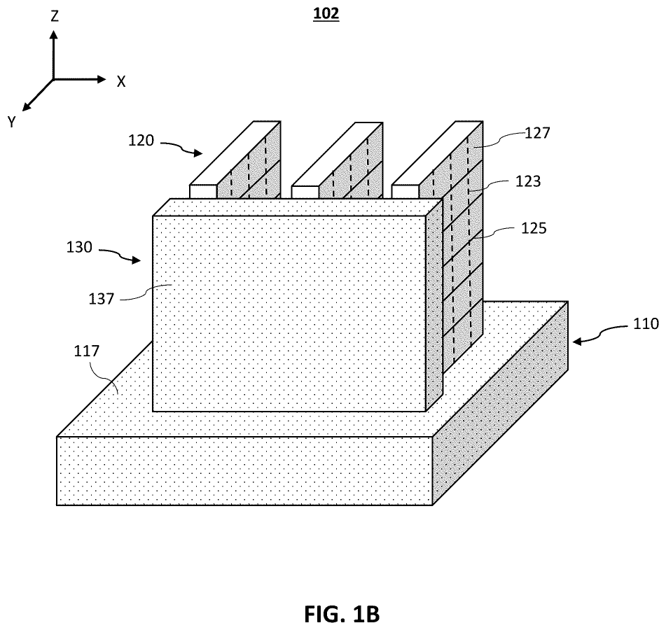

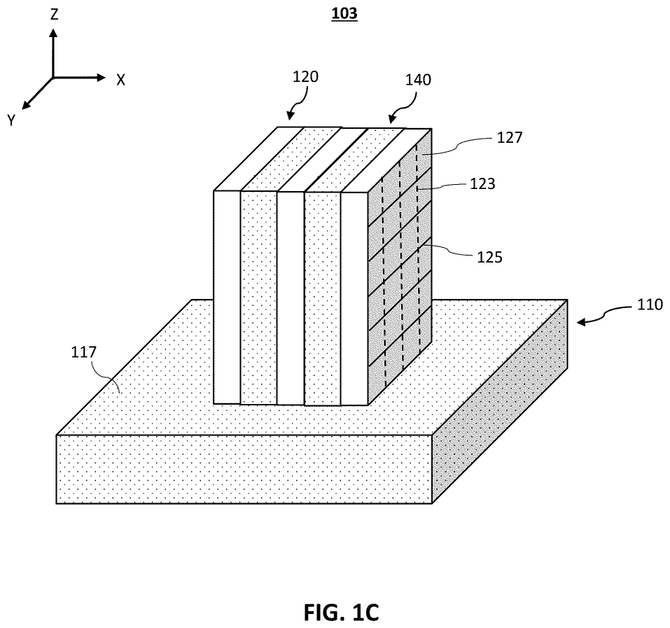

FIGS. 1A-1C illustrate IC devices including memory layers bonded to logic layers with orthogonal inclination, according to some embodiments of the disclosure. FIG. 1A shows an IC device 101 including a logic layer 110 and memory layers 120 (individually referred to as “memory layer 120”). In other embodiments, the IC device 101 may include fewer, more, or different components. For instance, the IC device 101 may include a different number of logic layer 110 or a different number of memory layer 120. As shown in FIG. 1A, the memory layers 120 are over the logic layer 110. The memory layers 120 are bonded to the logic layer 110 with orthogonal inclination. A surface 127 of each memory layer 120 may be perpendicular to a surface 117 of the logic layer 110. The surface 127 may be parallel to the Y-Z plane, and the surface 117 may be parallel to the X-Y plane. The memory layers 120 may be parallel to each other.

The logic layer 110 may be a logic die or logic wafer, which may also be referred to as a compute die/wafer or compute logic die/wafer. The logic layer 110 controls the memory layers 120. The logic layer 110 may include one or more logic circuits that control operations of the memory layers 120. A logic circuit may be a peripheral circuit. A logic circuit may include transistors fabricated through a CMOS process. For instance, the transistors can be used to form word line drivers, row decoders, sense amplifiers, column decoders, timers, multipliers, CMOS logic, SRAM cells, power delivery network, signal delivery network, or other types of devices or circuits in the logic layer 110. In some embodiments, the architecture of transistors in the logic layer 110 may be different from that of transistors in the memory layers 120. In an example, the transistors in the logic layer 110 may have nanoribbon or nanowire semiconductor structures, while transistors in the memory layers 120 may have fin semiconductor structures.

A row decoder may select which rows of memory cells in memory arrays to be accessed based on memory addresses. In some embodiments, the row decoder may receive an input signal with information indicating a memory address. The row decoder may decode the memory address and select the row(s) corresponding to the memory address. The row decoder may further activate the row(s), e.g., by selecting and enabling the word line 113 of each selected row. After a row is selected and activated, the logic circuit can perform read or write operations on the memory cells in the row. The row decoder may include a digital circuit that can be used to decode memory addresses, select rows of memory cells, or activate word lines. The digital circuit may include one or more logic gates.

A word line driver drives signals down word lines 113. In some embodiments, the word line driver may receive signals from another component of the logic layer 110 (e.g., a row decoder) or from a circuit outside the IC device 100. The word line driver may amplify the signals and apply the amplified signals to word lines, e.g., word lines selected by a row decoder. The word line driver can generate the necessary voltage levels to activate word lines. In some embodiments, the word line driver may be coupled to one or more row decoders and one or more word lines 113. The word line driver may be implemented between a row decoder and a word line 113. In other embodiments, the word line driver may be included in a row decoder. In some embodiments, the word line driver may include one or more inverters to drive word lines 113.

A column decoder selects which column(s) of memory cells in memory arrays to be accessed based on memory addresses received from a logic circuit. The column decoder may decode a column address and activate the corresponding column of memory cells. The column decoder may include a digital circuit that can take the column address as input and generate one or more control signals that activate the corresponding column of memory cells. The digital circuit may include a combination of logic gates, such as AND gates and inverters, to decode the address and generate the necessary control signals. The number of inputs and outputs of the column decoder may depend on the size of the memory array. For example, in a memory system with 8 columns, the memory column decoder would have 3 address inputs (since 2\hat{ }3=8) and 8 output signals, each corresponding to a specific column. When a particular column address is provided, the column decoder may activate the corresponding output signal, enabling the memory cells in that column for read or write operations. The row decoder and column decoder can facilitate efficient and accurate access to specific rows of memory cells within the memory array and can support retrieval and storage of data in computer systems.

A sense amplifier may amplify and restore weak signals, e.g., to a more robust and usable level. In some embodiments, for reading data from the memory layers 120, the sense amplifier may detect and amplify the small voltage difference between the stored data states, typically representing binary values of 0 and 1. By amplifying this voltage difference, the sense amplifier can enable accurate and reliable data retrieval. In some embodiments (e.g., embodiments having high speed data transmission), the sense amplifier may amplify weak signals to avoid signal degradation and noise during signal propagation so that the signals can be more immune to noise, which can enable more accurate data recovery. The sense amplifier may be a latch-based sense amplifier, differential sense amplifier, dynamic sense amplifier, or other types of sense amplifiers. In some embodiments, the sense amplifier may be coupled to one or more column decoders and one or more bit lines. The sense amplifier may be implemented between a column decoder and a bit line. For instance, signals may be processed by the column decoder, then amplified by the sense amplifier before being provided to the bit line.

Each memory layer 120 may be a memory die or memory wafer. As shown in FIG. 1A, each memory layer 120 includes bit lines 123 (individually referred to as “bit line 123”) and word lines 125 (individually referred to as “word line 125”). A bit line 123 may be coupled to a column decoder and a sense amplifier, as described above. A word line 125 may be coupled to a row decoder and a word line driver, as described above. In some embodiments, each memory layer 120 includes one or more memory arrays. A memory array may include memory cells arranged in rows and columns, one or more bit lines 123, and one or more word lines 125. An example memory cell may include a memory element and one or more access transistors. A row memory cells may be coupled to a common word line. A column of memory cells may be coupled to a common bit line. A memory cell may be activated or accessed (e.g., for data read or write operations) using the corresponding word line and bit line. In some embodiments, each memory layer 120 may be a DRAM device that includes DRAM arrays.

Each memory layer 120 may include one or more semiconductor structures, which may facilitate formation of transistors in the memory layer 120. A semiconductor structure provides semiconductor regions (e.g., channel region, source region, drain region, etc.) of backend transistors in the memory layer 120. For the purpose of simplicity and illustration, other components (e.g., gate, source electrode, drain electrode, etc.) of backend transistors are not shown in FIG. 1A. In some embodiments, a semiconductor structure may include a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a combination of semiconductor materials where one semiconductor material may be used for a channel portion of a transistor and another material, sometimes referred to as a “blocking material,” may be used between the channel portion and the support structure over which the transistor is provided. In some embodiments, the channel material may include a monocrystalline semiconductor, such as silicon (Si) or germanium (Ge). In some embodiments, the channel material may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistors implemented in the memory layers 120 are NMOS transistors), the channel portions of the channel material may advantageously include a III-V material having a high electron mobility, such as, but not limited to InGaAs, InP, InSb, and InAs. For some such embodiments, the channel portions of the channel material may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel portions of the channel material may be an intrinsic III-V material, i.e., a III-V semiconductor material not intentionally doped with any electrically active impurity. In alternate embodiments, a nominal impurity dopant level may be present within the channel portions of the channel material, for example to further fine-tune a threshold voltage Vt, or to provide HALO pocket implants, etc. Even for impurity-doped embodiments however, impurity dopant level within the channel portions of the channel material may be relatively low, for example below 10¹⁵ dopant atoms per cubic centimeter (cm⁻³), and advantageously below 10¹³ cm⁻³.

For some example P-type transistor embodiments (i.e., for the embodiments where the transistors implemented in the memory layers 120 are PMOS transistors), the channel portions of the channel material may advantageously be a group IV material having a high hole mobility, such as, but not limited to Ge or a Ge-rich SiGe alloy. For some example embodiments, the channel portions of the channel material may have a Ge content between 0.6 and 0.9, and advantageously may be at least 0.7. In some embodiments with highest mobility, the channel portions of the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portions of the channel material is

In some embodiments, a memory layer 120 may be bonded to a logic layer through a hybrid bonding interface (HBI). In some embodiments, hybrid bonding may be performed either on a wafer-level, e.g., wafers may be hybrid bonded before they are separated into dies. In other embodiments, hybrid bonding may be performed on a die-level, e.g., dies may be hybrid bonded after the corresponding wafers have been separated into dies. In general, hybrid manufacturing is described herein with reference to a first IC structure (e.g., a memory layer 120) and a second IC structure (e.g., the logic layer 110) bonded to one another using a bonding material. The first and second IC structures may be fabricated by different manufacturers, using different materials, or different manufacturing techniques. For each IC structure, the terms “bottom face” or “backside” of the structure may refer to the back of the IC structure, e.g., bottom of the support structure of a given IC structure, while the terms “top face” or “frontside” of the structure may refer to the opposing other face. When the top face of the first IC structure is bonded to the top face of the second IC structure, the structures are described as bonded “face-to-face” (f2f). When the top face of the first IC structure is bonded to the bottom face of the second IC structure or the bottom face of the first IC structure is bonded to the top face of the second IC structure, the structures are described as bonded “face-to-back” (f2b). When the bottom face of the first IC structure is bonded to the bottom face of the second IC structure, the structures are described as bonded “back-to-back” (b2b).

In some embodiments, bonding of the faces of the first and second IC structures may be performing using insulator-insulator bonding, e.g., as oxide-oxide bonding, where an insulating material of the first IC structure is bonded to an insulating material of the second IC structure. In some embodiments, a bonding material may be present in between the faces of the first and second IC structures that are bonded together. The bonding material may be applied to the one or both faces of the first and second IC structures that should be bonded and then the first and second IC structures are put together, possibly while applying a suitable pressure and heating up the assembly to a suitable temperature (e.g., to moderately high temperatures, e.g., between about 50 and 200 degrees Celsius) for a duration of time. In some embodiments, the bonding material may be an adhesive material that ensures attachment of the first and second IC structures to one another. In some embodiments, the bonding material may be an etch-stop material. In some embodiments, the bonding material may be both an etch-stop material and have suitable adhesive properties to ensure attachment of the first and second IC structures to one another. In some embodiments, the bonding material may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the hybrid bonding. Using an etch-stop material at the interface (i.e., the interface between the first and second IC structures) that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond the first and second IC structures together. In addition, an etch-stop material at the interface between the first and second IC structures that includes include silicon, nitrogen, and carbon, where the atomic percentage of any of these materials may be at least 1%, may be advantageous in terms of improving etch-selectivity of this material with respect to etch-stop materials that may be used in different of the first and second IC structures.

In some embodiments, no bonding material may be used, but there will still be a bonding interface resulting from the bonding of the first and second IC structures to one another. Such a bonding interface may be recognizable as a seam or a thin layer in the microelectronic assembly, using, e.g., selective area diffraction (SED), even when the specific materials of the insulators of the first and second IC structures that are bonded together may be the same, in which case the bonding interface would still be noticeable as a seam or a thin layer in what otherwise appears as a bulk insulator (e.g., bulk oxide) layer.

FIG. 1B shows an IC device 102 including the logic layer 110, the memory layers 120, and another logic layer 130. In other embodiments, the IC device 102 may include fewer, more, or different components. Similar to the IC device 101, the memory layers 120 in the IC device 102 are bonded to the logic layer 110 with orthogonal inclination. The surface 127 of each memory layer 120 is perpendicular to the surface 117 of the logic layer 110. Additionally, the memory layers 120 are bonded to the logic layer 130 with orthogonal incubation. The surface 127 of each memory layer 120 is perpendicular to a surface 137 of the logic layer 130. The surface 137 of the logic layer 130 may be perpendicular to the surface 117 of the logic layer 110. The surface 137 of the logic layer 130 is in a plane that is parallel to the X-Z plane. The memory layers 120 may be bonded to the logic layer 130 with hybrid bonding, such as the hybrid bonding described above.

In some embodiments, the logic layers 110 and 130 may include different logic circuits. For example, the bit lines 123 may be coupled to logic circuits (e.g., sense amplifiers or column decoders) in the logic layer 110, while the word lines 125 may be coupled to logic circuits (e.g., word line drivers or row decoders) in the logic layer 130. As another example, the bit lines 123 may be coupled to logic circuits in the logic layer 130, while the word lines 125 may be coupled to logic circuits in the logic layer 110. In other embodiments, the logic layers 110 and 130 may include the same logic circuit(s).

FIG. 1C shows an IC device 103 including the logic layer 110, the memory layers 120, and logic layers 140 (individually referred to as “logic layer 140”). In other embodiments, the IC device 103 may include fewer, more, or different components. For instance, the IC device 103 may include the logic layer 130 shown in FIG. 1B. Similar to the IC device 101, the memory layers 120 in the IC device 103 are bonded to the logic layer 110 with orthogonal inclination. The surface 127 of each memory layer 120 is perpendicular to the surface 117 of the logic layer 110. Additionally, the memory layers 120 are bonded to the logic layers 140. The memory layers 120 may be bonded to the logic layer 140 with hybrid bonding, such as the hybrid bonding described above. Each logic layer 140 is between two memory layers 120. The logic layer 140 may be in parallel with the memory layers 120. Each logic layer 140 may be orthogonal to the logic layer 110 and have a surface that is perpendicular to the surface 117.

In some embodiments, the logic layers 110 and 140 may include different logic circuits. For example, the bit lines 123 of a memory layer 120 may be coupled to logic circuits (e.g., sense amplifiers or column decoders) in the logic layer 110, while the word lines 125 of the memory layer 120 may be coupled to logic circuits (e.g., word line drivers or row decoders) in a logic layer 140 (e.g., the logic layer 140 bonded to the memory layer 120). As another example, the bit lines 123 of a memory layer 120 may be coupled to logic circuits in a logic layer 140, while the word lines 125 of the memory layer 120 may be coupled to logic circuits in the logic layer 110. In other embodiments, the logic layers 110 and 140 may include the same logic circuit(s).

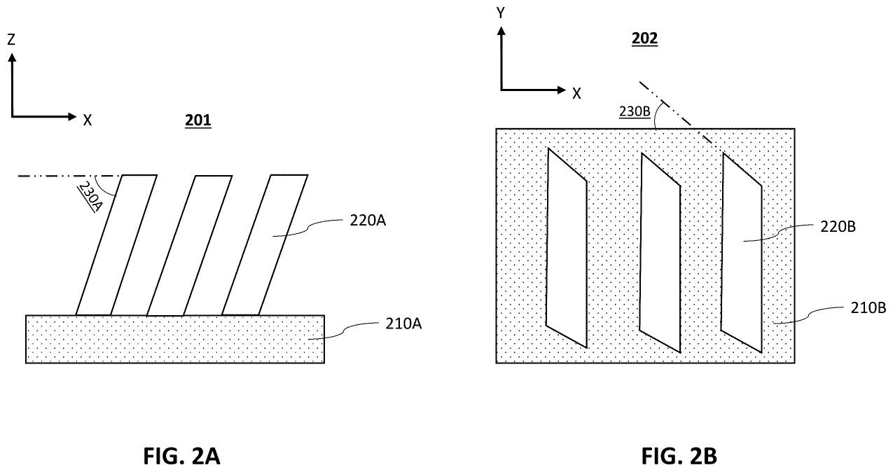

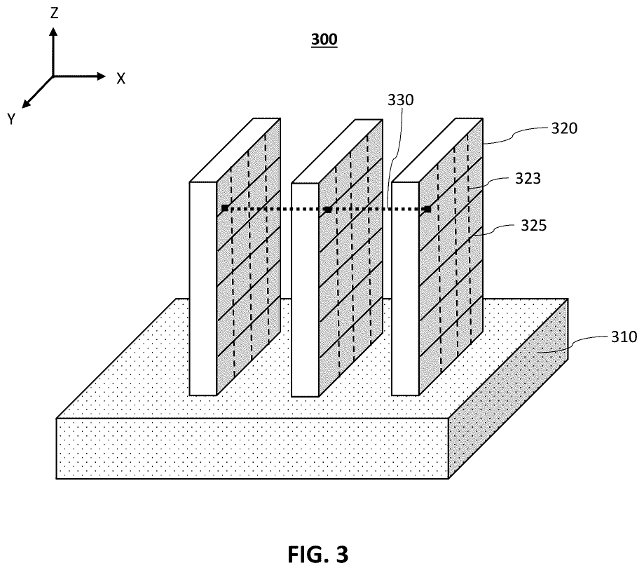

FIGS. 2A and 2B illustrate IC devices including memory layers bonded to logic layers with non-orthogonal inclination, according to some embodiments of the disclosure. For the purpose of illustration, FIG. 2A shows a side view of an IC device 201 in the X-Z plane. The IC device 201 includes a logic layer 210A and memory layers 220A (individually referred to as “memory layer 220A”). The logic layer 210A may be a logic die with circuits that can control the memory layers 220A. The logic layer 210A may include the same or similar logic circuits as the logic layer 110 in FIGS. 1A-1C. Each memory layer 220A may include the same or similar components as the memory layers 120 in FIGS. 1A-1C.

Different from the IC device 101 in FIG. 1A, the memory layers 220A in the IC device 201 are bonded to the logic layer 210A with non-orthogonal inclination. As shown in FIG. 2A, each memory layer 220A is at an angle 230A from the logic layer 210A. The angle 230A may be an acute angle. The memory layers 220A are parallel to each other in FIG. 2A. In other embodiments, the memory layers 220A may not be in parallel. The memory layers 220A may be bonded to the logic layer 210A through hybrid bonding, such as hybrid bonding described above.

FIG. 2B shows a top view of an IC device 202 in the X-Y plane. The IC device 202 includes a logic layer 210B and memory layers 220B (individually referred to as “memory layer 220B”). The logic layer 210B may be a logic die with circuits that can control the memory layers 220B. The logic layer 210B may include the same or similar logic circuits as the logic layer 110 in FIGS. 1A-1C. Each memory layer 220B may include the same or similar components as the memory layers 120 in FIGS. 1A-1C.

Different from the IC device 101 in FIG. 1A, the memory layers 220B in the IC device 201 are bonded to the logic layer 210B with non-orthogonal inclination. As shown in FIG. 2B, each memory layer 220B is at an angle 230B from the logic layer 210B. The angle 230B may be an acute angle. The memory layers 220B are parallel to each other in FIG. 2A. In other embodiments, the memory layers 220B may not be in parallel. The memory layers 220B may be bonded to the logic layer 210B through hybrid bonding, such as hybrid bonding described above.

FIG. 3 illustrates an IC device 300 including memory layers 320 with global word lines, according to some embodiments of the disclosure. The memory layers 320 may be examples of the memory layers 120 in FIGS. 1A-1C. Each memory layer 320 includes bits lines 323 (individually referred to as “bit line 323”) and word lines 325 (individually referred to as “word line 325”). The memory layers 320 are bonded to a logic layer with orthogonal inclination. In other embodiments, the memory layers 320 may be bonded to a logic layer with non-orthogonal inclination, such as the non-orthogonal inclination shown in FIGS. 2A and 2B. The logic layer 310 may be an example of the logic layer 110 in FIGS. 1A-1C.

In the embodiments of FIG. 3, the IC device 300 also includes a conductive structure 330, which is over the logic layer 310. The conductive structure 330 may be perpendicular to the memory layers 320. In some embodiments, the conductive structure 330 may be, or may include, one or more through-silicon vias. The conductive structure 330 is connected to a word line 325 of each of the memory layers 320. The three word lines 325 in the three memory layers 320 are coupled to each other through the conductive structure 330. These word lines 325 are referred to as global word lines, as they can be globally controlled, e.g., by a single word line driver or a single row decoder in the logic layer 310. In other embodiments, the IC device 300 may include more global word lines. Alternatively, the IC device 300 may include global bit lines, i.e., bit lines that are in different memory layers 320 but are electrically coupled so that these bit lines can be globally controlled, e.g., by a single sense amplifier or a single column decoder in the logic layer 310. In some embodiments, global bit lines or global word lines may be coupled through electrodes in transistors in different memory layers.

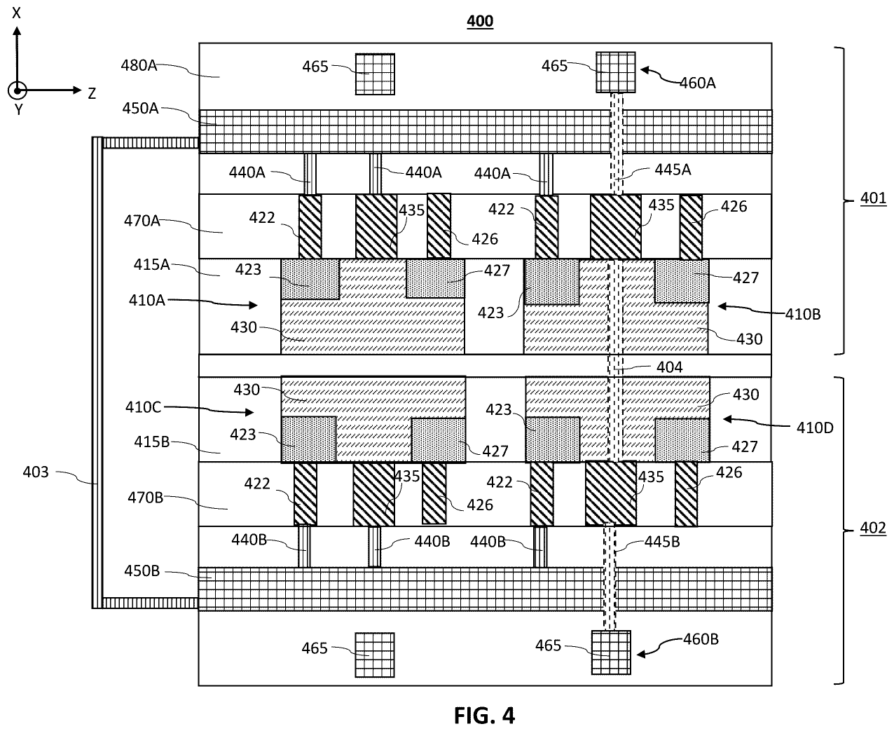

FIG. 4 illustrates an IC device 400 with transistors 410A-410D having global gate electrodes, according to some embodiments of the disclosure. The IC device 400 includes a memory device 401, another memory device 402, and conductive structures 403 and 404. The memory device 401 or 402 may be a portion of a memory array, such as one of the memory layers 120, 220A, 220B, or 320. The memory device 401 includes the transistors 410A and 410B, a support structure 415A, vias 440A (individually referred to as “via 440A”), a via 445A, a metal layer 450A, another metal layer 460A, and electrical insulators 470A and 480A. The memory device 402 includes the transistors 410C and 410D a support structure 415B, vias 440B (individually referred to as “via 440B”), a via 445B, a metal layer 450B, another metal layer 460B, and electrical insulators 470B and 480B. In other embodiments, the IC device 400 may include fewer, more, or different components. For instance, the IC device 400 may include more transistors, or other semiconductor devices not shown in FIG. 4. Also, the IC device 400 may include a different number of metal layers, vias, or electrical insulators.

The transistors 410A-410D are collectively referred to as “transistors 410” or “transistor 410.” The support structures 415A and 415B are collectively referred to as “support structures 415” or “support structure 415.” The vias 440A and 440B are collectively referred to as “vias 440” or “via 440.” The vias 445A and 445B are collectively referred to as “vias 445” or “via 445.” The metal layers 450A and 450B are collectively referred to as “metal layers 450” or “metal layer 450.” The metal layers 460A and 460B are collectively referred to as “metal layers 460” or “metal layer 460.” The electrical insulators 470A and 470B are collectively referred to as “electrical insulators 470” or “electrical insulator 470.” The electrical insulators 480A and 480B are collectively referred to as “electrical insulators 480” or “electrical insulator 480.”

Each support structure 415 may be any suitable structure, such as a substrate, a die, a wafer, or a chip, based on which the transistors 410 can be built. In some embodiments, each support structure 415 may be a semiconductor substrate composed of semiconductor material systems including, for example, N-type or P-type materials systems, and, in some embodiments, the channel region 430, described herein, may be a part of the support structure 415. In some embodiments, the semiconductor substrate may be a crystalline substrate formed using a bulk silicon or a silicon-on-insulator (SOI) substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group III-V, Group II-VI, or Group IV materials. In some embodiments, the substrate may be non-crystalline. In some embodiments, the support structure may be a printed circuit board (PCB) substrate. One or more transistors, such as the transistors 410 may be built on the support structure 415.

Although a few examples of materials from which the support structure 415 may be formed are described here, any material that may serve as a foundation upon which an IC may be built falls within the spirit and scope of the present disclosure. In various embodiments, the support structure 415 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 415 may provide material “support” in that, e.g., the IC devices/structures described herein are build based on the semiconductor materials of the support structure 415. However, in some embodiments, the support structure 415 may provide mechanical support.

A transistor 410 may be an access transistor in a memory cell or a transistor in a control circuit associated with a memory cell. In some embodiments, a transistor 410 may be a field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. The transistor 410 includes a semiconductor structure that includes a channel region 430, a source region 423, and a drain region 427. The transistor 410 includes a semiconductor structure that includes a channel region 430, a source region 423, and a drain region 427. The semiconductor structure of each transistor 410 may be at least partially in the support structure 415. The support structure 415 may include a semiconductor material, from which at least a portion of the semiconductor structure is formed. The semiconductor structure of a transistor 410 (or a portion of the semiconductor structure, e.g., the channel region 430) may be a planar structure or a non-planar structure. A non-planar structure is a three-dimensional structure, such as fin, nanowire, or nanoribbon. A non-planar structure may have a longitudinal axis and a transvers cross section perpendicular to the longitudinal axis. In some embodiments, a dimension of the non-planar structure along the longitudinal axis may be greater than dimensions along other directions, e.g., directions along axes perpendicular to the longitudinal axis.

Each channel region 430 includes a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group Il of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 400 nm, including all values and ranges therein.

For some example N-type transistor embodiments (i.e., for the embodiments where the transistor 410 is an NMOS transistor or an N-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1−xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 4015 dopant atoms per cubic centimeter (cm⁻³), and advantageously below 40¹³ cm⁻³. These materials may be amorphous or polycrystalline, e.g., having a crystal grain size between 0.5 nanometers and 400 nanometers.

For some example P-type transistor embodiments (i.e., for the embodiments where the transistor 410 is a PMOS transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 4015 cm⁻³, and advantageously below 40¹³ cm⁻³. These materials may be amorphous or polycrystalline, e.g., having a crystal grain size between 0.5 nanometers and 400 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front-end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 4:2:1. In various other examples, IGZO may have a gallium to indium ratio of 4:1, a gallium to indium ratio greater than 4 (e.g., 2:1, 3:1, 4:1, 5:1, 6:1, 7:1, 8:1, 9:1, or 40:1), and/or a gallium to indium ratio less than 4 (e.g., 4:2, 4:3, 4:4, 4:5, 4:6, 4:7, 4:8, 4:9, or 4:10). IGZO can also contain tertiary dopants such as aluminum or nitrogen.

In each transistor 410, the source region 423 and the drain region 427 are connected to the channel region 430. The source region 423 and the drain region 427 each include a semiconductor material with dopants. In some embodiments, the source region 423 and the drain region 427 have the same semiconductor material, which may be the same as the channel material of the channel region 430. A semiconductor material of the source region 423 or the drain region 427 may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur(S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region 423 and the drain region 427 are the same type. In other embodiments, the dopants of the source region 423 and the drain region 427 may be different (e.g., opposite) types. In an example, the source region 423 has N-type dopants and the drain region 427 has P-type dopants. In another example, the source region 423 has P-type dopants and the drain region 427 has N-type dopants. Example N-type dopants include Te, S, As, tin (Sn), Si, Ga, Se, S, In, Al, Cd, chlorine (Cl), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the source region 423 and the drain region 427 may be highly doped, e.g., with dopant concentrations of about 4·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region 423 and the drain region 427 may be the regions having dopant concentration higher than in other regions, e.g., higher than a dopant concentration in the channel region 430, and, therefore, may be referred to as “highly doped” (HD) regions.

The channel region 430 may include one or more semiconductor materials with doping concentrations significantly smaller than those of the source region 423 and the drain region 427. For example, in some embodiments, the channel material of the channel region 430 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region 423 and the drain region 427, for example below 40¹⁵ cm⁻³ or below 40¹³ cm⁻³. Depending on the context, the term “S/D terminal” may refer to a S/D region or a S/D contact or electrode of a transistor.

A transistor 410 also includes a source electrode 422 over the source region 423 and a drain electrode 426 over the drain region 427. The source electrode 422 is also referred to as a source electrode. The drain electrode 426 is also referred to as a drain electrode. The source electrodes 422 and the drain contacts 446 are electrically conductive and may be coupled to source and drain terminals for receiving electrical signals. A source electrode 422 or the drain electrode 426 includes one or more electrically conductive materials, such as metals. Examples of metals in the source electrodes 422 and the drain contacts 446 may include, but are not limited to, Ruthenium (Ru), copper (Cu), cobalt (Co), palladium (Pd), platinum (Pt), nickel (Ni), and so on.

In the embodiments of FIG. 4, the source electrode 422 of the transistor 410A may be separated from the source electrode 422 of the transistor 410C by one or more electrical insulators, e.g., the electrical insulators 470. The source electrode 422 of the transistor 410B may be separated from the source electrode 422 of the transistor 410D by one or more electrical insulators, e.g., the electrical insulators 470. The drain electrode 426 of the transistor 410A may be separated from the drain electrode 426 of the transistor 410C by one or more electrical insulators, e.g., the electrical insulators 470. The drain electrode 426 of the transistor 410B may be separated from the drain electrode 426 of the transistor 410D by one or more electrical insulators, e.g., the electrical insulators 470.

Each transistor 410 also includes a gate that is over or wraps around at least a portion of the channel region 430. The gate of the transistor 410 includes a gate electrode 435. The gate electrode 435 may also be referred to as a gate electrode. The gate of the transistor 410B includes a gate electrode 435. The gate electrode 435 can be coupled to a gate terminal that controls gate voltages applied on the transistor 410. In some embodiments, the gate electrode 435 may receive signals from a control circuit. The gate electrode may be coupled to a signal interconnect, such as the signal interconnect 312 in FIG. 3.

The gate electrode 435 may include one or more gate electrode materials, where the choice of the gate electrode materials may depend on whether the transistor 410 is a P-type transistor or an N-type transistor. For a P-type transistor, gate electrode materials that may be used in different portions of the gate electrode may include, but are not limited to, Ru, Pd, Pt, Co, Ni, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 435 may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

In the embodiments of FIG. 4, the gate electrode 435 of each transistor 410 is a global gate electrode, i.e., the gate electrode 435 of each transistor 410 is coupled to the gate electrode 435 of another transistor 410. As shown in FIG. 4, the conductive structure 403 is connected to the metal layers 450A and 450B. The metal layer 450A is coupled to the gate electrode 435 of the transistor 410A through a via 440A, and the metal layer 450B is coupled to the gate electrode 435 of the transistor 410C through a via 440B. This way, these two gate electrodes 435 are coupled and may be at the same electrical potential(s) during the operation of the IC device 400. The conductive structure 403 may have a different location or shape in other embodiments. For instance, the conductive structure 403 may be straight between the metal layer 450A and 450B, as opposed to a U shape shown in FIG. 4. At least part of the conductive structure 403 is perpendicular to the metal layer 450A or 450B. The conductive structure 404 is connected to the gate electrode 435 of the transistor 410B and the gate electrode 435 of the transistor 410D so these two gate electrodes 435 are coupled and may be at the same electrical potential(s) during the operation of the IC device 400.

In some embodiments, each gate electrode 435 may be coupled to a word line, e.g., a word line 223 in FIG. 2. The two word lines corresponding to the gate electrode 435 of the transistor 410A and the gate electrode 435 of the transistor 410C are coupled through the two gate electrodes and the conductive structure 403. Similarly, the two word lines corresponding to the gate electrode 435 of the transistor 410B and the gate electrode 435 of the transistor 410D are coupled through the two gate electrodes and the conductive structure 404. These word lines are global word lines. In some embodiments, the transistor 410A and the transistor 410B may be in two memory cells, respectively, that are in the same row of a memory array, and the gate electrode 435 of the transistor 410A and the gate electrode 435 of the transistor 410B are coupled to the same word line. The transistor 410C and the transistor 410D may be in two memory cells, respectively, that are in the same row of another memory array, and the gate electrode 435 of the transistor 410C and the gate electrode 435 of the transistor 410D are coupled to the same word line.

The gate of each transistor 410 may also include a gate insulator (not show in FIG. 4) that separates at least a portion of the channel region 430 from the gate electrode so that the channel region 430 is insulated from the gate electrode. In some embodiments, the gate insulator may wrap around at least a portion of the channel region 430. The gate insulator may also wrap around at least a portion of the source region 423 or the drain region 427. At least a portion of the gate insulator may be wrapped around by the gate electrode. The gate insulator includes an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

In the embodiments of FIG. 4, the metal layer 450 is the first metal layer at the frontside of the memory device 401 or 401. The metal layer 460 is the second metal layer at the frontside and is further from the transistor 410 than the metal layer 450. The metal layer 450 may be referred to as M0, and the metal layer 460 may be referred to as M1. Even though FIG. 4 shows a single metal line in the metal layer 450, the metal layer 450 may include one or more other metal lines. A metal line in the metal layer 450 may have a longitudinal axis along the X axis. The metal layer 460 includes metal lines 465, individually referred to as metal line 465. A metal line may be an electrically conductive structure. A metal line may also be referred to as a conductive line, a metal track, a conductive track, or an interconnect. In some embodiments, a metal line may include one or more metals, such as tungsten (W), molybdenum (Mo), ruthenium (Ru), copper (Cu), other metals, or some combination thereof. Metal lines are shown as rectangles in FIG. 4 for the purpose of simplicity and illustration. A metal line may have different shapes in other embodiments. A metal line may have a transvers cross section perpendicular to its longitudinal axis.

The metal layers 450 and 460 may be electrically coupled to the transistors 410. For instance, the metal layer 450 is coupled to the source electrodes 422 of the transistors 410 through the vias 440. Each via 440 has an end connected to the metal layer 450 and another end connected to a source electrode 422. The metal layer 460 is coupled to the gate electrodes 435 of the transistors 410 through the vias 445. Each via 445 has an end connected to a metal line 465 and another end connected to a gate electrode 435. In some embodiments, the metal layer 450 may facilitate operations of the transistors 410 by providing power to the transistors 410. The metal layer 460 may facilitate operations of the transistors 410 by providing signals to the transistors 410. In some embodiments, the metal layer 450 may function as bit line of a memory array, and the metal layer 460 may function as a word line of a memory array. A via 440 or 445 may include a metal, such as tungsten (W), molybdenum (Mo), ruthenium (Ru), copper (Cu), or other metals. In some embodiments, the IC device 400 may include one or more additional metal layers (not shown in FIG. 4) above the metal layer 460. The IC device 400 may include one or more additional vias connected to the one or more additional metal layer.

The electrical insulators 470 and 480 may separate conductive structures and semiconductor structures in the IC device 400 from each other so that they are shorted to each other. The electrical insulator 470 or 480 includes one or more electrically insulative materials. An electrically insulative material may be a dielectric material, hysteretic material, and so on. Example dielectric material includes oxide (e.g., Si based oxides, metal oxides, etc.), nitride (e.g., Si based nitride, etc.), low-k dielectric, high-k dielectric, and so on. Example hysteretic material include ferroelectric materials, antiferroelectric materials, and so on. In some embodiments, a portion of the electrical insulator 470 or 480 may include a first electrical insulator and a second electrical insulator with the second electrical insulator at least partially surrounding the first electrical insulator.

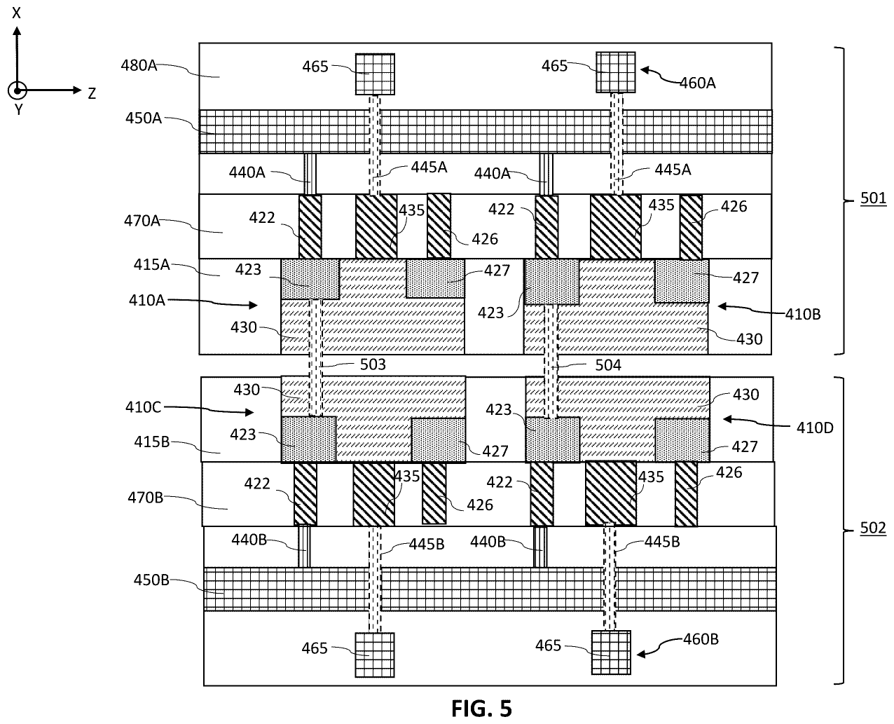

FIG. 5 illustrates an IC device 500 with transistors 410A-410D having global gate electrodes, according to some embodiments of the disclosure. The IC device 500 includes a memory device 501, another memory device 502, and conductive structures 503 and 504. The memory device 501 or 502 may be a portion of a memory layer, such as one of the memory layers 120, 220A, 220B, or 320. The memory device 501 may be the same or similar as the memory device 401 in FIG. 4. The memory device 502 may be the same or similar as the memory device 402 in FIG. 4. In other embodiments, the IC device 500 may include fewer, more, or different components.

Different from the IC device 400, the gate electrode 435 in the IC device 500 are not global gate electrodes. The gate electrode 435 of the transistor 410A is not coupled to the gate electrode 435 of the transistor 410C. The gate electrode 435 of the transistor 410A may be separated from the gate electrode 435 of the transistor 410C by one or more electrical insulators, e.g., the electrical insulators 470. The gate electrode 435 of the transistor 410B is not coupled to the gate electrode 435 of the transistor 410D. The gate electrode 435 of the transistor 410B may be separated from the gate electrode 435 of the transistor 410D by one or more electrical insulators, e.g., the electrical insulators 470.

In the embodiments of FIG. 5, the source electrodes 422 are global source electrode. The source electrode 422 of each transistor 410 is coupled to the source electrode 422 of another transistor 410. As shown in FIG. 5, the source electrode 422 of the transistor 410A is coupled to the source electrode 422 of the transistor 410C through the conductive structure 503, and the source electrode 422 of the transistor 410B is coupled t the source electrode 422 of the transistor 410D through the conductive structure 504. In other embodiments, the conductive structure 503 may be used to couple the drain electrode 426 of the transistor 410A is coupled to the drain electrode 426 of the transistor 410C. The conductive structure 504 may be used to couple the drain electrode 426 of the transistor 410B is coupled to the drain electrode 426 of the transistor 410D.

In some embodiments, each source electrode 422 (or each drain electrode 426) may be coupled to a bit line, e.g., a bit line 123 or 323. The two bit lines corresponding to the source electrode 422 (or the drain electrode 426) of the transistor 410A and the source electrode 422 (or the drain electrode 426) of the transistor 410C are coupled to each other through the two source electrodes 422 (or the two drain electrodes 426) and the conductive structure 503. Similarly, the two bit lines corresponding to the source electrode 422 (or the drain electrode 426) of the transistor 410B and the source electrode 422 (or the drain electrode 426) of the transistor 410D are coupled to each other through the two source electrodes 422 (or the two drain electrodes 426) and the conductive structure 504. These bit lines are global bit lines. In some embodiments, the transistor 410A and the transistor 410B may be in two memory cells, respectively, that are in the same column of a memory array, and the source electrode 422 of the transistor 410A and the source electrode 422 of the transistor 410B are coupled to the same bit line. The transistor 410C and the transistor 410D may be in two memory cells, respectively, that are in the same column of another memory array, and the source electrode 422 of the transistor 410C and the source electrode 422 of the transistor 410D are coupled to the same bit line.

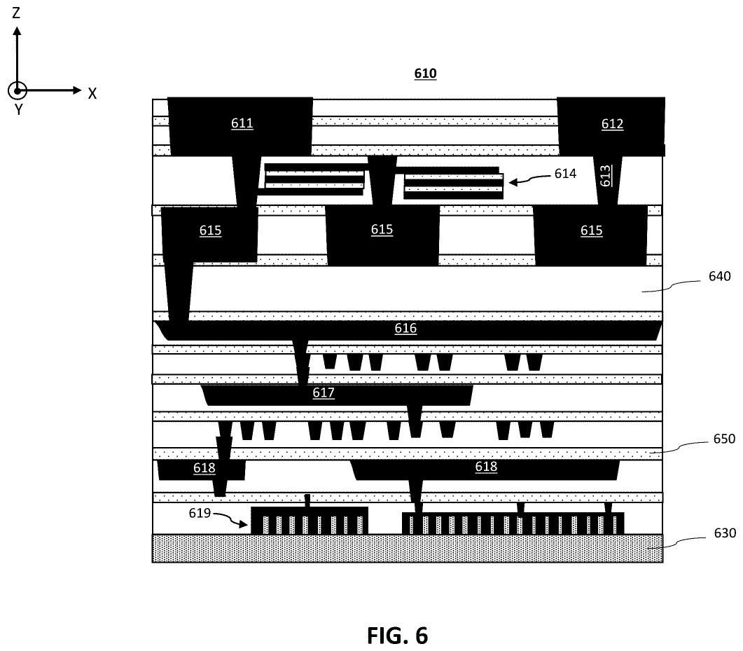

FIG. 6 illustrates a logic layer 610 with a power interconnect 611 and a signal interconnect 612, according to some embodiments of the disclosure. In addition to the power interconnect 611 and signal interconnect 612, the logic layer 610 further includes vias 613 (individually referred to as “via 613”), two capacitors 614 (individually referred to as “capacitor 614”), interconnects 615, 616, 617, and 618, two interposers 619 (individually referred to as “interposer 619”), a support structure 630, electrical insulator 640, and dielectric layers 650. In other embodiments, the logic layer 610 may include fewer, more, or different components. Also, the components in the logic layer 610 may be arranged differently. The logic layer 610 may be an example of the logic layer 110, 210A, 210B, or 310.

The support structure 630 may be a semiconductor substrate composed of semiconductor material systems including, for example, N-type or P-type materials systems. In one implementation, the support structure 630 may be a crystalline substrate formed using a bulk SOI substructure. In other implementations, the support structure 630 may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of Group III-V materials (i.e., materials from groups III and V of the periodic table of elements), Group II-VI (i.e., materials from groups Il and IV of the periodic table of elements), or Group IV materials (i.e., materials from Group IV of the periodic table of elements). In some embodiments, the support structure 630 may be non-crystalline. In some embodiments, the support structure 630 may be a PCB substrate. Although a few examples of materials from which the support structure 630 may be formed are described here, any material that may serve as a foundation upon which IC devices of the logic layer 610 as described herein may be built falls within the spirit and scope of the present disclosure.

In some embodiments, the support structure 630 may be in a FEOL section of the logic layer 610. The support structure 630 may include one or more semiconductor devices, such as transistors. The transistors may include FET, such as metal-oxide-semiconductor FET (MOSFET), tunnel FET (TFET), fin-based transistor (e.g., FinFET), nanoribbon-based transistor, nanowire-based transistor, GAA transistor, other types of FET, or a combination of both. In some embodiments, the support structure 630 may include one or more semiconductor structures. A semiconductor structure may be a non-planar structure, such as fin, nanoribbon, and so on.

The power interconnect 611 is a conductive structure, such as a metal line. The power interconnect 611 may facilitate power delivery to circuits or devices in the logic layer 610 and one or more memory layers bonded to the logic layer 610. The power interconnect 611 may be, or otherwise be coupled to, a power plane. In some embodiments, the power interconnect 611 may be coupled to electrodes of transistors (e.g., electrodes over source regions or over drain regions of transistors) in the logic layer 610 and the memory layer. The power interconnect 611 may be at the same or similar electric potential as the electrodes during the operation of the logic die or the memory layer(s). A memory layer may include no power delivery structures so that more memory array may be arranged in the memory layer.

The capacitors 614 are coupled to the power interconnect 611 to facilitate power delivery. Each capacitor includes conductive layers and dielectric layers. For the purpose of simplicity and illustration, the conductive layers are represented by solid black rectangles and the dielectric layers are represented by dot patterned rectangles in FIG. 6. A conductive layer of capacitor 614 on the left in FIG. 6 may be connected to the power interconnect 611. Another conductive layer of capacitor 614 on the left may be connected to a via 613. The via 613 may also be connected to a conductive layer of capacitor 614 on the right in FIG. 6.

The signal interconnect 612 is also a conductive structure, such as a metal line. The signal interconnect 612 may facilitate signal transmission between the logic layer 610 and a memory layer. The signal interconnect 612 may be coupled to electrodes of transistors (e.g., gate electrodes over channel regions of transistors) in the logic layer 610 or the memory layer. The signal interconnect 612 may be at the same or similar electric potential as the gate electrodes during the operation of the logic layer 610 or the memory layer. In some embodiments, the power interconnect 611 or signal interconnect 612 may be coupled to components (e.g., transistors, capacitors, etc.) of memory layers.

The interconnects 615, 616, 617, and 618 are also electrically conductive structures, e.g., metal lines, metal layers, etc. The power interconnect 611, signal interconnect 612, and interconnects 615, 616, 617, and 618 may be in a BEOL section of the logic layer 610. The BEOL section may include a plurality of BEOL layers stacked over each other, such as a first BEOL layer including the two interconnects 618 (individually referred to as “interconnect 618”), a second BEOL layer including the interconnect 617, a third BEOL layer including the interconnect 616, a fourth BEOL layer including the three interconnects 615 (individually referred to as “interconnect 615”), and a sixth BEOL layer including the power interconnect 611 and signal interconnect 612.

The vias 613 facilitates electrical connections among the power interconnect 611, signal interconnect 612, and interconnects 615, 616, 617, and 618. A via 613 may be connected to one or more other vias 613 or to one or more interconnects (e.g., one or more of the power interconnect 611, signal interconnect 612, and interconnects 615, 616, 617, and 618). Some of the vias 613 may facilitate power delivery through the power interconnect 611. Some of the vias 613 may facilitate signal transmission from circuits or devices in the support structure 630 to one or more memory layers through the signal interconnect 612. Even though not shown in FIG. 6, the logic layer 610 may include one or more vias that are connected to transistors in the support structure 630.

The interposers 619 facilitate electrical connection between the support structure 630 (e.g., transistor in the support structure 630) to components in the BEOL section of the logic layer 610. An interposer 619 may include a semiconductor layer (e.g., a silicon layer) and a plurality of TSVs extending from a top surface of the semiconductor layer to the bottom surface of the semiconductor layer. The TSVs may be connected to one or more vias 613 and coupled to one or more interconnects in the BEOL section. In some embodiments, the interposers 619 may be in the FEOL section.

At least some of the conductive components of the logic layer 610 (e.g., the power interconnect 611, signal interconnect 612, interconnects 615, 616, 617, and 618, vias 613, etc.) may be separated from each other by the electrical insulator 640. The dielectric layers 650 may also be insulative. In some embodiments, the dielectric layers 650 may be hard masks, which may facilitate formation of the at least some of conductive components of the logic layer 610.

FIG. 7 illustrates a memory layer 710, according to some embodiments of the disclosure. The memory layer includes two transistors 711 (individually referred to as “transistor 711”), two capacitors 712 (individually referred to as “transistor 712”), interconnects 713 and 714, and various vias 715 (individually referred to as “via 715”), an electrical insulator 716, and various dielectric layers 717 (individually referred to as “dielectric layer 717”). In other embodiments, a memory layer 710 may include fewer, more, or different components. The memory layer 710 may be an example of the memory layers 120, 220A, 220B, or 320.

The transistors 711 and capacitors 712 may be formed in a BEOL process. The transistors 711 are coupled to the capacitors 712. In some embodiments, each capacitor 712 is coupled to an electrode of the corresponding transistor 711. The electrode may be a source electrode that is over a source region of the transistor 711 or a drain electrode that is over a drain region of the transistor 711. In some embodiments, each transistor 711 may be an access transistor of a memory cell, and the capacitor 712, which is coupled to the transistor 711, may be a memory element of the memory cell. The two transistors 711 and two capacitors 712 may be in two memory cells. In other embodiments, each memory layer 710 may include a different number of memory cells.

The interconnects 713 and 714 and vias 715 are conductive structures in the memory layers 710 and can facilitate delivery of power or signals to the memory cells. Each conductive structure may include one or more metals, such as tungsten (W), molybdenum (Mo), ruthenium (Ru), copper (Cu), other metals, or some combination thereof. In some embodiments, the interconnects 713 and 714 and vias 715 are coupled to the transistor 711 and capacitors 712. In FIG. 7, the interconnect 713 is connected to a via 715, and the interconnect 714 may be connected to terminals of the capacitors 712. Even though not shown in FIG. 7, a via 715 may be connected to another via, an electrode (e.g., gate electrode, source electrode, or drain electrode) of a transistor 711, or a terminal of a capacitor 712.

The electrical insulator 716 may include a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc. The dielectric layers 717 may also be insulative. In some embodiments, a dielectric layer 717 may be a hard mask that can facilitate formation of the at least some of conductive structures in the memory layers 710.

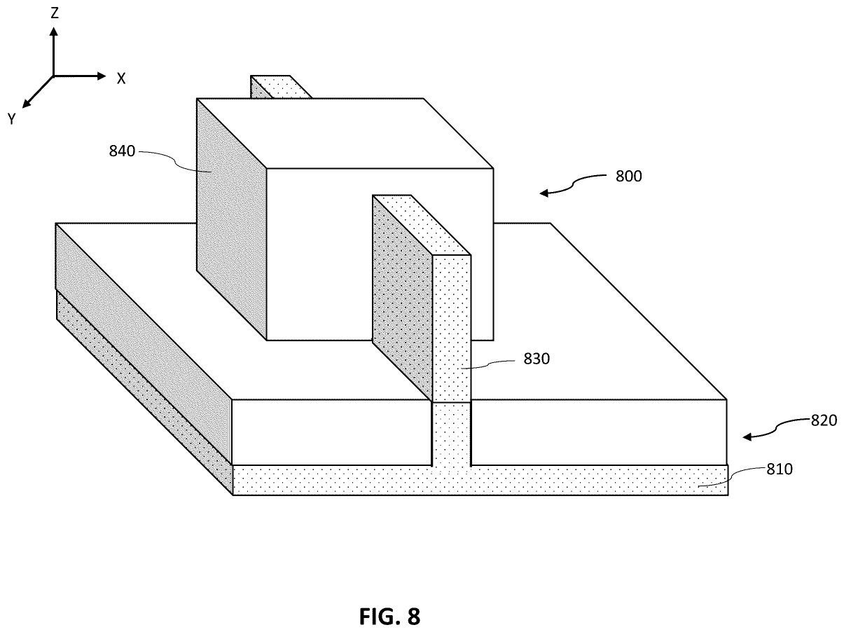

FIG. 8 shows a transistor 800 with a fin, according to some embodiments of the disclosure. The transistor 800 may be an embodiment of a transistor in a logic layer (e.g., the logic layer 110, 210A, 210B, or 310) or in a memory layer (e.g., the memory layer 120, 220A, 220B, or 320). The transistor 800 is over a support structure 810 and a dielectric layer 820. The transistor 800 includes a semiconductor structure 830 and a gate 840. In other embodiments, the transistor 800 may include fewer, more, or different components. For instance, the transistor 800 may include multiple semiconductor structures 830.

The support structure 810 may be any suitable structure, such as a substrate, a die, a wafer, or a chip, based on which transistors can be built. The support structure 810 may be an embodiment of the support structure 415 in FIG. 4. The dielectric layer 820 is over various portions of the support structure 810 along the Z axis. The dielectric layer 820 includes one or more dielectric materials, such as oxide or other low-k dielectric materials. Example oxide in the dielectric layer may include silicon oxide (SiO), silicon oxycarbide (SiOC), silicon oxycarbonitride (SiOCN), and so on.

The semiconductor structures 830 are over the support structure 810. In the embodiments of FIG. 1, the semiconductor structures 830 have a fin shape with a longitudinal axis parallel to the Y axis and a transverse cross section parallel to the X-Z plane. A dimension of a semiconductor structure 830 along the Y axis may be greater than a dimension of the semiconductor structure 830 in another direction. The semiconductor structure 830 may provide the source region, channel region, and drain region of the transistor 800. A channel region of a transistor may include a channel material, such as channel materials described above. The source region and drain region in a transistor are connected to the channel region. The source region and drain region may each include a semiconductor material with dopants. In some embodiments, the source region and drain region have the same semiconductor material, which may be the same as the channel material of the channel region.

The dimensions of the semiconductor structures 830 may be different for different applications of the transistor 800. For example, compared with embodiments where the transistor 800 is used in a memory die, the cross section of each semiconductor structure 830 in the X-Z plane may be larger when the transistor 800 is used in a logic die. The width of each semiconductor structure 830 along the X axis may also be larger when the transistor 800 is used in a logic die.

The gate 840 is over the dielectric layer 820. In FIG. 8, the gate 840 wraps around the semiconductor structures 830. The gate 840 and the semiconductor structures 830 may form GAA transistors. The gate 840 may include a gate electrode including one or more conductive materials, such as metal, polycrystalline silicon, other types of conductive materials, or some combination thereof. In some embodiments, the choice of the conductive materials in the gate 840 may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, the gate 840 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. The gate 840 may also include a gate insulator, part of which may be between the gate electrode and each semiconductor structure 830. The gate 840 may be electrically coupled to a power plane, ground plane, or signal plane for facilitating power supply or signal transmission for the transistor 800.

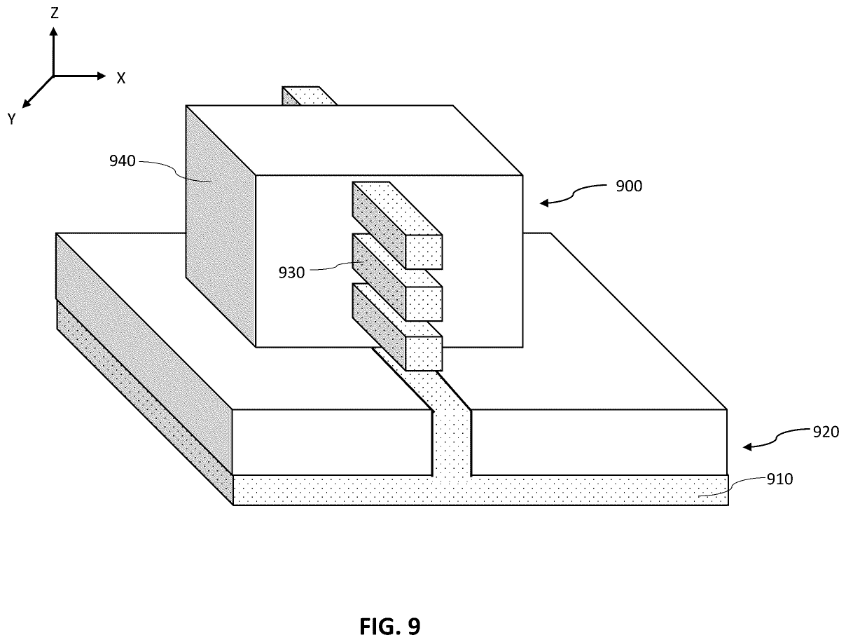

FIG. 9 shows a transistor 900 with nanoribbons, according to some embodiments of the disclosure. The transistor 900 may be an embodiment of a transistor in a logic layer (e.g., the logic layer 110, 210A, 210B, or 310) or in a memory layer (e.g., the memory layer 120, 220A, 220B, or 320). The transistor 900 is over a support structure 910 and a dielectric layer 920. The transistor 900 includes a plurality of semiconductor structures 930 (individually referred to as “semiconductor structure 930”), which are stacked over each other along the Z axis, and a gate 940. In other embodiments, the transistor 900 may include fewer, more, or different components. For instance, the transistor 900 may include a different number of semiconductor structures. Semiconductor structures may be arranged differently in the transistor 900. For instance, two or more semiconductor structures may be stacked over each other along the X axis.

The support structure 910 may be any suitable structure, such as a substrate, a die, a wafer, or a chip, based on which transistors can be built. The support structure 910 may be an embodiment of the support structure 415 in FIG. 4. The dielectric layer 920 is over various portions of the support structure 910 along the Z axis. The dielectric layer 920 includes one or more dielectric materials, such as oxide or other low-k dielectric materials. Example oxide in the dielectric layer may include silicon oxide (SiO), silicon oxycarbide (SiOC), silicon oxycarbonitride (SiOCN), and so on.

The semiconductor structures 930 are over the support structure 910. In the embodiments of FIG. 1, the semiconductor structures 930 have a nanoribbon shape with a longitudinal axis substantially parallel to the Y axis and a transverse cross section substantially parallel to the X-Z plane. A dimension of a semiconductor structure 930 along the Y axis may be greater than a dimension of the semiconductor structure 930 in another direction. The semiconductor structures 930 are arranged parallel to each other and are stacked in a direction along the Z axis. In other embodiments, a semiconductor structure 930 may have a different shape, e.g., fin, other non-planar shapes, or a planar shape.

A semiconductor structure 930 may provide the source region, channel region, and drain region of at least one transistor. A channel region of a transistor may include a channel material, such as channel materials described above. The source region and drain region in a transistor are connected to the channel region. The source region and drain region may each include a semiconductor material with dopants. In some embodiments, the source region and drain region have the same semiconductor material, which may be the same as the channel material of the channel region.

The dimensions of the semiconductor structures 930 may be different for different applications of the transistor 900. For example, compared with embodiments where the transistor 900 is used in a memory die, the cross section of each semiconductor structure 930 in the X-Z plane may be larger when the transistor 900 is used in a logic die. The width of each semiconductor structure 930 along the X axis may also be larger when the transistor 900 is used in a logic die. In some embodiments, the transistor 900 may be used in either a logic layer or a memory layer. A nanoribbon transistor in a logic layer may include more nanoribbons (e.g., approximately one to three times more) than a nanoribbon transistor in a memory layer. In some embodiments, the transistor 900 may be a transistor in a logic layer, and a transistor in a memory layer may be a FinFET.

The gate 940 is over the dielectric layer 920. In FIG. 9, the gate 940 wraps around the semiconductor structures 930. The gate 940 and the semiconductor structures 930 may form GAA transistors. The gate 940 may include a gate electrode including one or more conductive materials, such as metal, polycrystalline silicon, other types of conductive materials, or some combination thereof. In some embodiments, the choice of the conductive materials in the gate 940 may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, the gate 940 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. The gate 940 may also include a gate insulator, part of which may be between the gate electrode and each semiconductor structure 930. The gate 940 may be electrically coupled to a power plane, ground plane, or signal plane for facilitating power supply or signal transmission for the transistor 900.

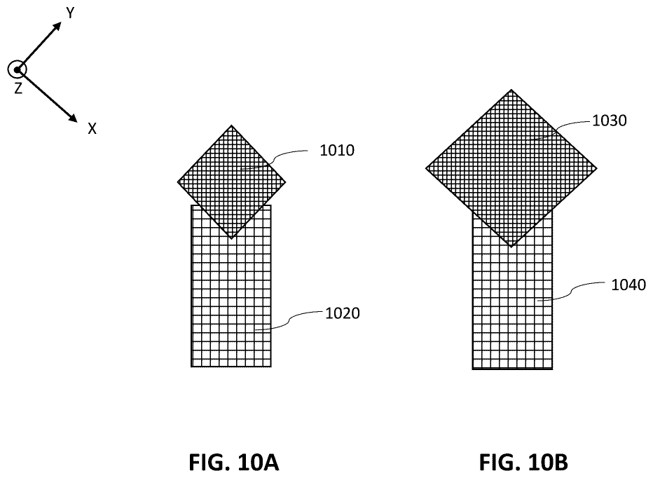

FIG. 10A illustrates semiconductor regions 1010 and 1020 of a transistor in a memory die, according to some embodiments of the disclosure. The transistor is also referred to as a memory transistor. The transistor may be an access transistor in a memory cell or a transistor in a peripheral circuit of the memory die. The memory transistor may be an embodiment of the transistors 410 in FIG. 4.

FIG. 10B illustrates semiconductor regions 1030 and 1040 of a transistor in a logic die, according to some embodiments of the disclosure. The transistor is also referred to as a logic transistor. The logic transistor may be an embodiment of the transistors 410 in FIG. 4. For the purpose of illustration, FIGS. 10A and 10B do not show other components of the transistors.

As shown in FIG. 10A, the semiconductor region 1010 wraps around a portion of the semiconductor region 1020. The semiconductor region 1010 may be a source region or drain region of the memory transistor. The semiconductor region 1020 may be a channel region of the memory transistor. In some embodiments, the semiconductor region 1010 (or a semiconductor structure including the semiconductor region 1010) may be a non-planar structure, such as a fin or nanoribbon. The semiconductor region 1010 can be formed over the semiconductor region 1020 through an epitaxy process or a layer transfer process.

In FIG. 10B, the semiconductor region 1030 wraps around a portion of the semiconductor region 1040. The semiconductor region 1030 may be a source region or drain region of the logic transistor. The semiconductor region 1040 may be a channel region of the logic transistor. In some embodiments, the semiconductor region 1030 (or a semiconductor structure including the semiconductor region 1030) may be a non-planar structure, such as a fin or nanoribbon. The semiconductor region 1030 can be formed over the semiconductor region 1040 through an epitaxy process or a layer transfer process.

In some embodiments, the cross section of the semiconductor region 1010 in the X-Y plane is smaller than the cross section of the semiconductor region 1030 in the X-Y plane. A width of the semiconductor region 1020 along the X axis may be approximately 5% to approximately 50% larger than the width of the semiconductor region 1010 along the X axis. For purpose of illustration, the cross section of the semiconductor region 1010 in FIG. 10A and the cross section of the semiconductor region 1030 in FIG. 10A each has a shape of a parallelogram with sharp corners. In other embodiments, the cross section of the semiconductor region 1010 or the semiconductor region 1030 can have other shapes, e.g., a curved shape with round corners.

In some embodiments, a transistor in a logic die may have more (e.g., approximately one to three times more) nanoribbon structures than a transistor in a memory die. The shape of the semiconductor region 1010 may be different from the shape of the semiconductor region 1020 in some embodiments. For instance, the semiconductor region 1010 may be a fin, while the semiconductor region 1020 may be a nanoribbon or nanowire.

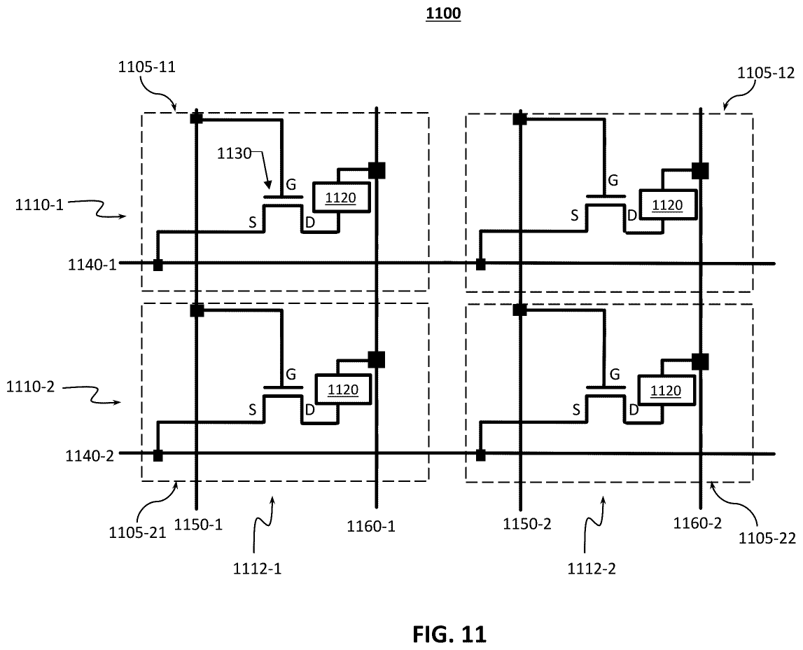

FIG. 11 is an electric circuit diagram of an example DRAM array 1100, according to some embodiments of the present disclosure. The DRAM array 1100 may be a memory array in a memory layer, such as one of the memory layers 120, 220A, 220B, 320, and 710. As shown in FIG. 11, the DRAM array 1100 is an array of memory cells 1105-11, 1105-12, 1105-21, and 1105-22 (collectively referred to as “memory cells 1105” or “memory cell 1105”), which are arranged in rows 1110-1 and 1110-2 (collectively referred to as “rows 1110” or “row 1110”) and columns 1112-1 and 1112-2 (collectively referred to as “columns 1112” or “column 1112”). Each memory cell 1105 is illustrated within one of the dashed boxes in FIG. 11. Each memory cell 1105 may be a DRAM cell. In other embodiments, the DRAM array 1100 may include a different number of memory cells 1105, a different number of rows 1110, or a different number of columns 1112.

The DRAM array 1100 also includes three types of control lines: bit lines 1140-1 and 1140-2 (collectively referred to as “bit lines 1140” or “bit line 1140”), word lines 1150-1 and 1150-2 (collectively referred to as “word lines 1150” or “word line 1150”), and plate lines 1160-1 and 1160-2 (collectively referred to as “plate lines 1160” or “plate line 1160”), which control the memory cells 1105. The memory cells 1105 in the row 1110-1 are coupled to the same bit line 1140-1. The memory cells in the row 1110-1 are coupled to the same bit line 1140-2. The memory cells in the column 1112-1 are coupled to the same word line 1150-2 and the same plate line 1160-2. The memory cells in the column 1112-2 are coupled to the same word line 1150-1 and the same plate line 1160-1. As is conventionally used in context of memory, the terms “row” and “column” do not reflect the, respectively, horizontal and vertical orientation on a page of a drawing illustrating a memory array but, instead, reflect how individual memory cells are addressed. Namely, memory cells 1105 sharing a single bit line 1140 are said to be in the same row, while memory cells sharing a single word line 1150 and a single plate line 1160 are said to be on the same column. In other embodiments, the DRAM array 1100 may include a different number of memory cells, bit lines, word lines, or plate lines. Furthermore, in other embodiments, the memory cells 1105 may be arranged in arrays in a manner other than what is shown in FIG. 11, e.g., in any suitable manner of arranging memory cells into arrays as known in the art, all of which being within the scope of the present disclosure.

A memory cell 1105 may store one bit of binary information. Each memory cell 1105 is a 1T-1X memory cell. The memory cell 1105 includes a memory element 1120 and an access transistor 1130. The memory element 1120 is configured to store signals. The memory element 1120 may have more than one state. The memory element 1120 having two states may be referred to as a binary memory element. In other embodiments, the memory element 1120 may have more than two states. In some embodiments, the memory element 1120 is a capacitor that can store electrical voltage signals, and the memory cell 1105 is a one-transistor one-capacitor (1T-1C) memory cell. In other embodiments, the memory element 1120 may be, for example, a ferroelectric memory element, a magnetic storage element, a resistor, or another transistor, coupled to the access transistor 1130. Also, the memory element 1120 may store signals other than electrical voltage signals.

The access transistor 1130 controls access to the memory cell 1105. For instance, the access transistor 1130 controls access to write information to the memory cell 1105, access to read information from the memory cell 1105, or both. The access transistor 1130 has a gate terminal, a source terminal, and a drain terminal, indicated in the example of FIG. 11 as terminals G, S, and D, respectively. An embodiment of the access transistor 1130 may be a vertical transistor, such as the vertical transistor 115 described above in conjunction in FIG. 1.

The access transistor 1130 may be a nanowire-based or nanoribbon-based transistor (or, simply, a nanowire transistor or nanoribbon transistor). In a nanowire or nanoribbon transistor, a gate stack that may include a stack of one or more gate electrode metals and, optionally, a stack of one or more gate insulators may be provided around a portion of an elongated semiconductor structure called “nanowire or nanoribbon”, forming a gate on all sides of the nanowire or nanoribbon. The portion of the nanowire or nanoribbon around which the gate stack wraps around is referred to as a “channel” or a “channel portion.” A semiconductor material of which the channel portion of the nanoribbon is formed is commonly referred to as a “channel material.” A source region and a drain region are provided on the opposite ends of the nanowire or nanoribbon, on either side of the gate stack, forming, respectively, a source and a drain of such a transistor. Wrap-around or all-around gate transistors, such as nanoribbon and nanowire transistors, may provide advantages compared to other transistors having a non-planar architecture, such as FinFETs, and transistors having planar architecture. In the following, the terms “terminal” and “electrode” may be used interchangeably. Furthermore, for S/D terminals, the terms “terminal” and “region” may be used interchangeably.

As shown in FIG. 11, the gate terminal of the access transistor 1130 is coupled to a word line 1150, one of the S/D terminals of the access transistor 1130 is coupled to a bit line 1140, and the other one of the S/D terminals of the access transistor 1130 is coupled to a first terminal of the memory element 1120, e.g., a first electrode of a capacitor. As also shown in FIG. 11, the other terminal of the memory element 1120 may be coupled to a capacitor plate line 1160. As is known in the art, word line, bit line, and plate line may be used together to read and program the memory element 1120. In some embodiments (e.g., embodiments where the access transistor 1130 is the vertical transistor 115), a portion of the bit line 1140 may be a S/D region of the access transistor 1130. Another S/D region of the access transistor 1130 is coupled to the memory element 1120. Also, a portion of the word line 1150 may be a gate electrode of the access transistor 1130. Such vertical transistors can improve the memory cell density of the DRAM array 1100 so that more memory cells can be arranged in the available space of the DRAM array 1100.

Each of the bit line 1140, the word line 1150, and the plate line 1160, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

In the embodiment of FIG. 11, a single plate line 1160 is shared among multiple memory cells 1105 of a given row. The plate lines 1160 are shared among the same memory cells 1105 among which the word line 1150 are shared. Such an arrangement where the plate lines 1160 are shared among the same memory cells among which the word lines 1150 are shared may be described as an arrangement where the plate lines 1160 are “parallel” to the word lines 1150. Each memory cell 1105 of the DRAM array 1100 where the plate lines 1160 are parallel to the word lines 1150, e.g., as shown in FIG. 11, may then be addressed (e.g., to perform READ and WRITE operations) by using the word line 1150 and the plate line 1160 corresponding to the column 1112 to which the memory cell 1105 belongs and by using the bit line 1140 corresponding to the row 1110 to which the memory cell 1105 belongs.

It should be noted that, just as the horizontal and vertical orientations on a page of an electrical circuit diagram illustrating a memory array does imply functional division of memory cells into rows and columns as used in common language, the orientation of various elements on a page of an electrical circuit diagram illustrating a memory array does not imply that the same orientation is used for the actual physical layout of a memory array. For example, in an IC device implementing the DRAM array 1100 as shown in FIG. 2A, corresponding bit lines 1140 and plate lines 1160 (i.e., a pair of a bit line 1140 and a plate line 1160 coupled to a given column 1112) do not have to physically extend in a direction parallel to one another (although they may), or the word lines 1150 do not have to physically extend in a direction perpendicular to the bit lines 1140 (although they may). In another example, in an IC device implementing the DRAM array 1100 as shown in FIG. 11, corresponding word lines 1150 and plate lines 1160 (i.e., a pair of a word line 1150 and a plate line 1160 coupled to a given column 1112) do not have to physically extend in a direction parallel to one another (although they may), or the word lines 1150 do not have to physically extend in a direction perpendicular to the bit lines 1140 (although they may).

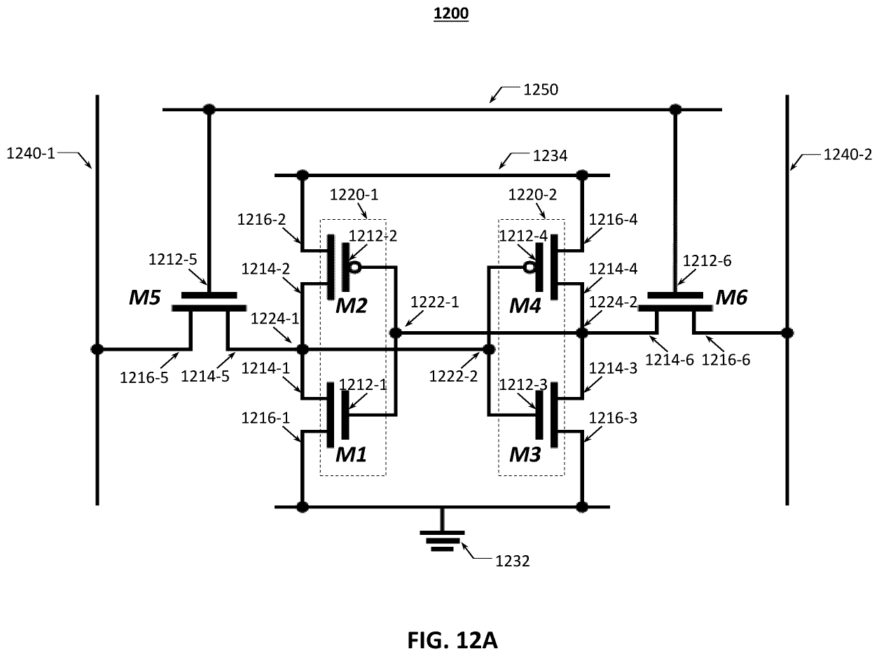

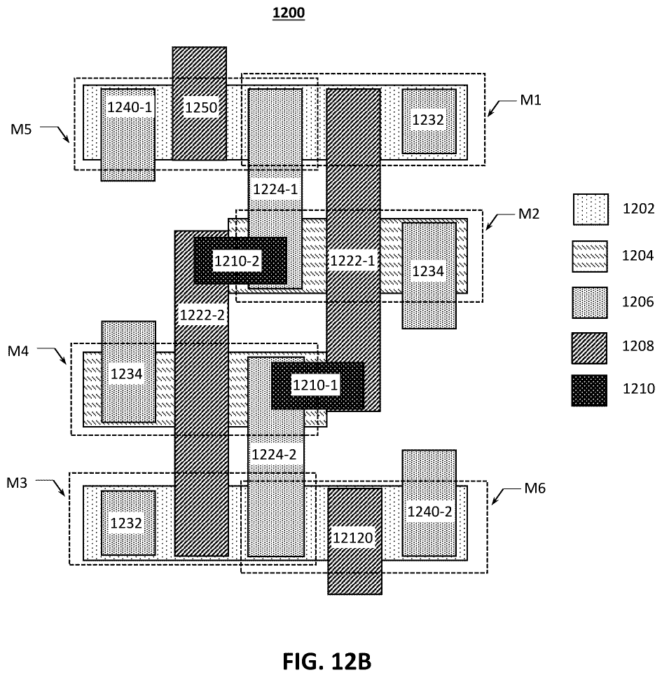

FIG. 12A is an electric circuit diagram of an example SRAM cell 1200, according to some embodiments of the present disclosure. The SRAM cell 1200 may be in a logic layer, such as the logic layer 110, 210A, 210B, 310, or 610. In some embodiments, the SRAM cell 1200 may be used in an SRAM array. As shown in FIG. 12B, the SRAM cell 1200 includes transistors M1-M4 for storing a bit value or a memory state (e.g., logic “1” or “0”) of the cell, and two access transistors, M5 and M6, for controlling access to the cell (e.g., access to write information to the cell or access to read information from the SRAM cell 1200). The SRAM cell 1200 is a 6-transistor (6T) memory cell. In other embodiments, the SRAM cell 1200 may include a different number of transistors. Each of the transistors M1-M6 may have any transistor architecture (e.g., planar or non-planar, FinFET, nanoribbon/nanowire, etc.). For example, the transistors M1-M6 may have the transistor architecture shown in FIG. 4 or FIG. 5. An example of the transistors M1-M6 may be one of the transistors 222 in FIG. 2.

In the SRAM cell 1200, each bit may be stored on four transistors (M1, M2, M3, M4) that form two cross-coupled inverters 1220, each having an input 1222 and an output 1224. The first inverter 1220-1 may be formed by an NMOS transistor M1 and a PMOS transistor M2, while the second inverter 1220-2 may be formed by an NMOS transistor M3 and a PMOS transistor M4. As shown in FIG. 12B, the gate stack 1212-1 of the transistor M1 may be coupled to the gate stack 1212-2 of the transistor M2, and both of these gate stacks may be coupled to the input 1222-1 of the first inverter 1220-1. On the other hand, the first S/D region 1214-1 of the transistor M1 may be coupled to the first S/D region 1214-2 of the transistor M2, and both of these first S/D regions 1214-1 and 1214-2 may be coupled to the output 1224-1 of the first inverter 1220-1. Similarly, for the second inverter 320-2, the gate stack 1212-3 of the transistor M3 may be coupled to the gate stack 1212-4 of the transistor M4, and both of these gate stacks may be coupled to the input 1222-2 of the second inverter 1220-2, while the first S/D region 1214-3 of the transistor M3 may be coupled to the first S/D region 1214-4 of the transistor M4, and both of these first S/D regions 1214-3 and 1214-4 may be coupled to the output 1224-2 of the second inverter 1220-2. As also shown in FIG. 12B, when the transistors M1 and M3 are NMOS transistors and when the transistors M2 and M4 are PMOS transistors as illustrated in FIG. 12B, the second S/D regions 1216-1 and 1216-3 of the transistors M1 and M3 may be coupled to a ground voltage 1232, while the second S/D regions 1216-2 and 1216-4 of the transistors M2 and M4 may be coupled to a supply voltage 1234, e.g., VDD. In the embodiments of the SRAM cell 1200 where the NMOS transistors shown in FIG. 12B are replaced with PMOS transistors and vice versa, the designation of the ground voltage 1232 and the supply voltage 1234 would be reversed as well, all of which embodiments being within the scope of the present disclosure.

The four transistors M1-M4 in such configuration form a stable storage cell for storing a bit value of 0 or 1. As further shown in FIG. 12B, two additional access transistors, M5 an M6, may serve to control the access to the storage cell of the transistors M1-M4 during read and write operations. As shown in FIG. 12B, the first S/D region 1214-5 of the access transistor M5 may be coupled to the output 1224-1 of the first inverter 1220-1. Phrased differently, the first S/D region 1214-5 of the access transistor M5 may be coupled to each of the first S/D region 1214-1 of the transistor M1 and the first S/D region 1214-2 of the transistor M2. The second S/D region 1216-5 of the access transistor M5 may be coupled to a first bit line 1240-1. Thus, each of the first S/D region 1214-1 of the transistor M1 and the first S/D region 1214-2 of the transistor M2 may be coupled to the first bit line 1240-1 (e.g., via the access transistor M5). The gate 1212-5 of the access transistor M5 may be coupled to a word line 1250.

As further shown in FIG. 12B, the first S/D region 1214-6 of the access transistor M6 may be coupled to the output 1224-2 of the second inverter 1220-2. Phrased differently, the first S/D region 1214-6 of the access transistor M6 may be coupled to each of the first S/D region 1214-3 of the transistor M3 and the first S/D region 1214-4 of the transistor M4. The second S/D region 1216-6 of the access transistor M6 may be coupled to a second bit line 1240-2. Thus, each of the first S/D region 1214-3 of the transistor M3 and the first S/D region 1214-4 of the transistor M4 may be coupled to the second bit line 1240-2 (e.g., via the access transistor M6). The gate 1212-6 of the access transistor M6 may be coupled to the word line 1250. Thus, the gates 1212-5 and 1212-6 of both of the access transistors M5 and M6 may be coupled to a single, shared, word line, the word line 1250.

As also shown in FIG. 12B, the input 1222-1 of the first inverter 1220-1 may be coupled to the first S/D region 1214-6 of the access transistor M6, while the input 1222-2 of the second inverter 1220-2 may be coupled to the first S/D region 1214-5 of the access transistor M5. In other words, each of the gate stack 1212-1 of the transistor M1 and the gate stack 1212-2 of the transistor M2 may be coupled to the first S/D region 1214-6 of the access transistor M6, while each of the gate stack 1212-3 of the transistor M3 and the gate stack 1212-4 of the transistor M4 may be coupled to the first S/D region 1214-5 of the access transistor M5. Phrased differently, each of the gate stack 1212-1 of the transistor M1 and the gate stack 1212-2 of the transistor M2 may be coupled to the second bit line 1240-2 (e.g., via the access transistor M6), while each of the gate stack 1212-3 of the transistor M3 and the gate stack 1212-4 of the transistor M4 may be coupled to the first bit line 1240-1 (e.g., via the access transistor M5).

The word line 1250 and the first and second bit lines 1240 may be used together to read and program (i.e., write to) the SRAM cell 1200. In particular, access to the cell may be enabled by the word line 1250 which controls the two access transistors M5 and M6 which, in turn, control whether the SRAM cell 1200 should be connected to the bit lines 1240-1 and 1240-2. During operation of the SRAM cell 1200, a signal on the first bit line 1240-1 may be complementary to a signal on the second bit line 1240-2. The two bit lines 1240 may be used to transfer data for both read and write operations. In other embodiments of the SRAM cell 1200, only a single bit line 1240 may be used, instead of two bitlines 1240-1 and 1240-2, although having one signal bit line and one inverse, such as the two bit lines 1240, may help improve noise margins.

During read accesses, the bit lines 1240 are actively driven high and low by the inverters 1220 in the SRAM cell 1200. This may improve SRAM bandwidth compared to DRAM. The symmetric structure of the SRAM cell 1200 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e. higher bits followed by lower bits, over the same package pins in order to keep their size and cost down.

Each of the word line 1250 and the bit lines 1240, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 12B provides a top-down plan view of an example implementation of the SRAM cell 1200, according to some embodiments of the present disclosure. FIG. 12B illustrates how the six transistors M1-M6 shown in FIG. 12B may be implemented. Several elements from FIG. 12B are labelled in FIG. 12B. For example, the transistors M1-M6 are labelled in FIG. 12B, with the approximate boundaries of the individual transistors shown in FIG. 12B with dashed rectangles. Certain elements, e.g., the specific S/D regions 1214 and 1216 and the gate stacks 1212, are not labelled in FIG. 12B in order to not clutter the drawings.

FIG. 12B illustrates that transistors M1 and M5 may be provided along a first region of an N-type semiconductor 1202, transistors M2 and M4 may each be provided along a respective first and second region of a P-type semiconductor 1204, and the transistors M4 and M6 may be provided along a second region of the N-type semiconductor 1202. Each of the regions of the N-type semiconductor 1202 and P-type semiconductor 1204 may be formed in a support structure (e.g., a substrate) or over a support structure, e.g., as a fin or nanoribbon. The N-type semiconductor 1202 is suitable for forming transistors of a first type, e.g., NMOS transistors, while the P-type semiconductor 1204 is suitable for forming transistors of a second type, e.g., PMOS transistors, thus realizing NMOS transistors M1, M3, M5, and M6, and PMOS transistors M2 and M4, as shown in FIG. 12B.

In the plan view shown in FIG. 12B, S/D contacts 1206, gate electrodes 1208, and interconnects 1210 are formed over the N-type and P-type semiconductors 1202 and 1204, e.g., as layers processed over the N-type and P-type semiconductors 1202 and 1204. While not specifically shown in FIG. 12B, S/D regions may be formed under the S/D contacts 1206, and gate dielectrics may be formed under the gate electrodes 1208. Any of the materials and processes described with respect to FIG. 4 may be used to form the transistors shown in FIG. 12B.

More specifically, a shared gate stack may be used to realize the gate stack 1212-1 of the transistor M1 coupled to the gate stack 1212-2 of the transistor M2. The shared gate stack is labelled 1222-1 in FIG. 12B, representing a node that is the input 1222-1 of the first inverter 1220-1 of the SRAM cell 1200. Similarly, a shared gate stack may be used to realize the gate stack 1212-3 of the transistor M3 coupled to the gate stack 1212-4 of the transistor M4 3. The shared gate stack is labelled 1222-2 in FIG. 12B, representing a node that is the input 1222-2 of the second inverter 1220-2 of the SRAM cell 1200.

As also shown in FIG. 12B, a first shared S/D contact may be used to realize the first S/D region 1214-1 of the transistor M1 coupled to the first S/D region 1214-2 of the transistor M2. The first shared S/D contact is labelled 1224-1 in FIG. 12B, representing a node that is the output 1224-1 of the first inverter 1220-1 of the SRAM cell 1200. Similarly, a second shared S/D contact may be used to realize the first S/D region 1214-3 of the transistor M3 coupled to the first S/D region 1214-4 of the transistor M4. The first shared S/D contact is labelled 1224-2 in FIG. 12B, representing a node that is the output 1224-2 of the second inverter 1220-2 of the SRAM cell 1200.

A first interconnect 1210-1, shown in FIG. 12B, may then be used to couple the shared gate stack 1222-1 of the first inverter 1220-1 to the shared S/D contact 1224-2 of the second inverter 1220-2, thus realizing the coupling of the input 1222-1 of the first inverter 1220-1 to the output 1224-2 of the second inverter 1220-2, shown in FIG. 12B. Similarly, a second interconnect 1210-2, shown in FIG. 12B, may then be used to couple the shared gate stack 1222-2 of the second inverter 1220-2 to the shared interconnect 1224-1 of the first inverter 1220-1, thus realizing the coupling of the input 1222-2 of the second inverter 1220-2 to the output 1224-1 of the first inverter 1220-1, shown in FIG. 12B.

FIG. 12B further illustrates that, in a given SRAM cell 1200, the first S/D region 1214-5 of the transistor M5 may be shared with (e.g., be the same as) the first S/D region 1214-1 of the transistor M1 (since both of these transistors are implemented in a single region of the N-type semiconductor 1202). In addition, the first S/D region 1214-3 of the transistor M3 may be shared with (e.g., be the same as) the first S/D region 1214-6 of the transistor M6 (since both of these transistors are implemented in a single region of the N-type semiconductor 1202).

Both of the second S/D region 1216-1 of the transistor M1 and the second S/D region 1216-3 of the transistor M3 may be coupled to the ground voltage 1232, as was described with reference to FIG. 12B. Both of the second S/D region 1216-2 of the transistor M2 and the second S/D region 1216-4 of the transistor M4 may be coupled to the supply voltage 1234, as was described with reference to FIG. 12B.

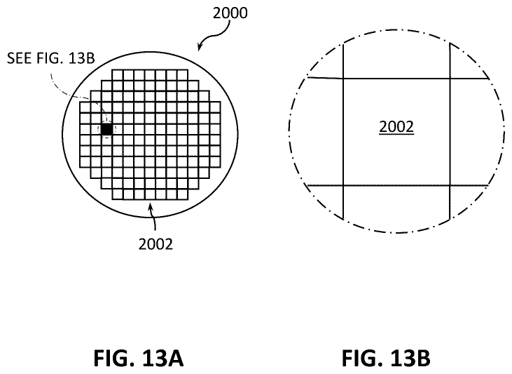

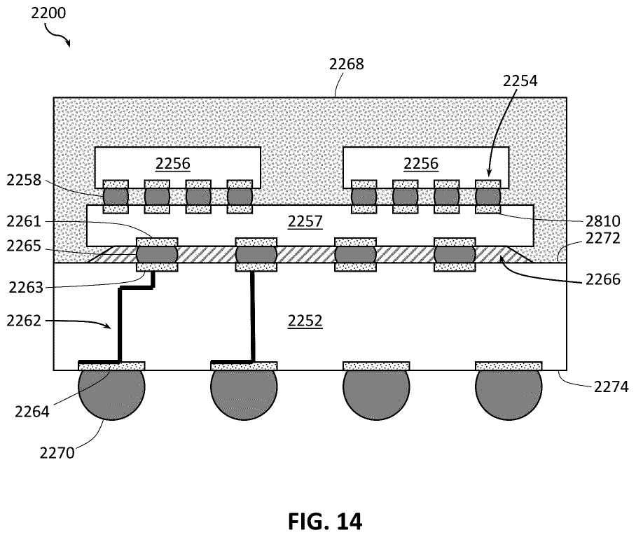

FIGS. 13A and 13B are top views of a wafer 2000 and dies 2002 that can facilitate memory layers bonded to one or more logic layers with inclination, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 14. The wafer 2000 may be composed of semiconductor material and may include one or more dies 2002 having IC devices formed on a surface of the wafer 2000. Each of the dies 2002 may be a repeating unit of a semiconductor product that includes any suitable IC. After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include memory layers bonded to one or more logic layers with inclination as disclosed herein may take or include components that take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 14 is a side, cross-sectional view of an example IC package 2200 that may include memory layers bonded to one or more logic layers with inclination, according to some embodiments of the disclosure. In some embodiments, the IC package 2200 may be a system-in-package (SiP).

As shown in FIG. 14, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 14 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 14 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

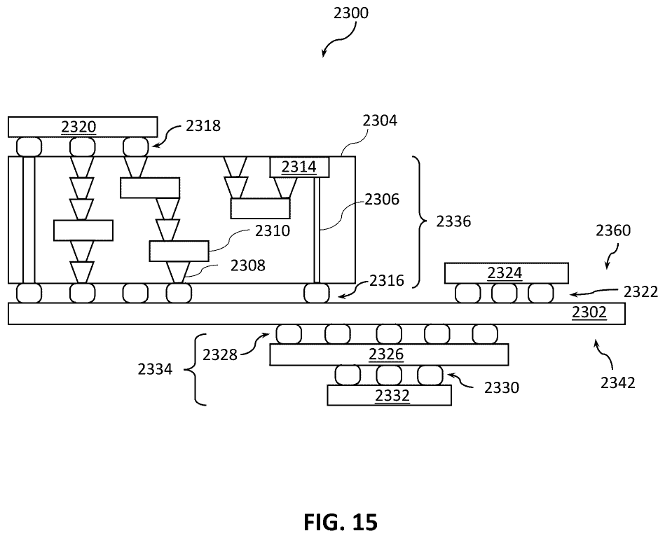

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 14 are solder balls (e.g., for a ball grid array (BGA) arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 15.

The dies 2256 may take the form of any of the embodiments of the die 2002 discussed herein and may include any of the embodiments of an IC device with memory layers bonded to one or more logic layers with inclination. In embodiments in which the IC package 2200 includes multiple dies 2256, the IC package 2200 may be referred to as a multi-chip package. Importantly, even in such embodiments of an MCP implementation of the IC package 2200, one or more IC devices with memory layers bonded to one or more logic layers with inclination may be provided in a single chip, in accordance with any of the embodiments described herein. The dies 2256 may include circuitry to perform any desired functionality. For example, one or more of the dies 2256 may be ESD protection dies, one or more of the dies 2256 may be logic dies (e.g., silicon-based dies), one or more of the dies 2256 may be memory dies (e.g., high bandwidth memory), etc.

The IC package 2200 illustrated in FIG. 14 may be a flip chip package, although other package architectures may be used. For example, the IC package 2200 may be a BGA package, such as an embedded wafer-level BGA package. In another example, the IC package 2200 may be a wafer-level chip scale package or a panel fan-out package. Although two dies 2256 are illustrated in the IC package 2200 of FIG. 14, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 15 is a cross-sectional side view of an IC device assembly 2300 that may include components having memory layers bonded to one or more logic layers with inclination, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include memory layers bonded to one or more logic layers with inclination in accordance with any of the embodiments disclosed herein; e.g., any of the IC packages discussed below with reference to the IC device assembly 2300 may take the form of any of the embodiments of the IC package 2200 discussed above with reference to FIG. 14 (e.g., may include memory layers bonded to one or more logic layers with inclination).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 15 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 14), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 13B), an IC device (e.g., the IC device 100, 200, 300, 600, or 700), or any other suitable component. In particular, the IC package 2320 may include memory layers bonded to one or more logic layers with inclination as described herein. Although a single IC package 2320 is shown in FIG. 15, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a loose pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 15, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further radio frequency (RF) devices, power amplifiers, power management devices, antennas, arrays, sensors, and microelectromechanical systems (MEMS) devices may also be formed on the interposer 2304. In some embodiments, memory layers bonded to one or more logic layers with inclination as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 15 includes a package-on-package structure 2334 coupled to the second face 2342 of the circuit board 2302 by coupling components 2328. The package-on-package structure 2334 may include an IC package 2326 and an IC package 2332 coupled together by coupling components such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

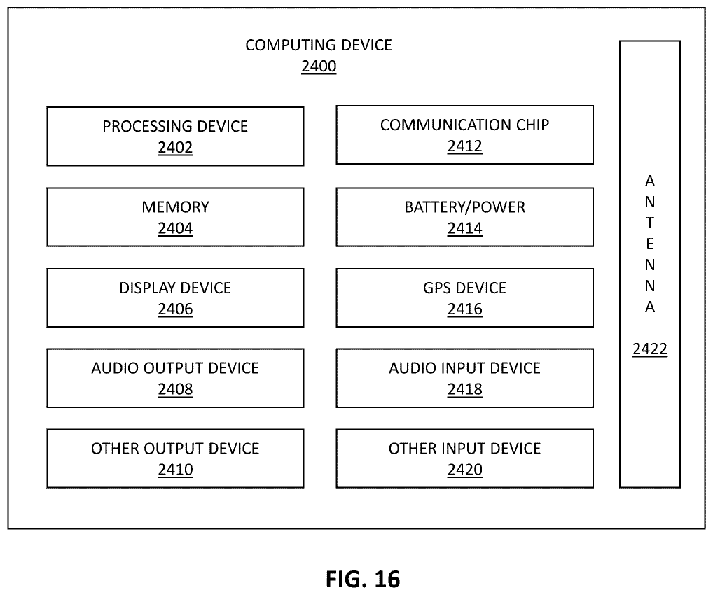

FIG. 16 is a block diagram of an example computing device 2400 that may include one or more components with memory layers bonded to one or more logic layers with inclination, according to some embodiments of the disclosure. For example, any suitable ones of the components of the computing device 2400 may include one or more dies (e.g., the die 2002 of FIG. 13B) that can facilitate memory layers bonded to one or more logic layers with inclination, according to some embodiments of the disclosure. Any of the components of the computing device 2400 may include an IC device (e.g., the IC device 100, 200, 300, 600, or 700) and/or an IC package (e.g., the IC package 2200 of FIG. 14). Any of the components of the computing device 2400 may include an IC device assembly (e.g., the IC device assembly 2300 of FIG. 15).

A number of components are illustrated in FIG. 16 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 16, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), CPUs, GPUs, cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a first memory layer including a first memory cell and having a first surface; a second memory layer including a second memory cell and having a second surface; and a logic layer including a logic circuit and having a third surface, the logic circuit coupled to the first memory cell or the second memory cell, in which: the first memory layer and the second memory layer are over the third surface, the first surface or the second surface are at an angle from the third surface, and the angle is in a range from 0 to 90 degrees.

Example 2 provides the IC device according to example 1, further including an additional logic layer including an additional logic circuit and having a fourth surface, in which the additional logic layer is over the third surface, and the fourth surface is perpendicular to the first surface or the second surface.

Example 3 provides the IC device according to example 2, in which: the logic circuit is coupled to a bit line of the first memory cell or the second memory cell, and the additional logic circuit is coupled to a word line of the first memory cell or the second memory cell.

Example 4 provides the IC device according to example 2 or 3, in which the logic circuit includes a word line driver that is coupled to the first memory cell or the second memory cell, and the additional logic circuit includes a sense amplifier coupled to the first memory cell or the second memory cell.

Example 5 provides the IC device according to any one of examples 1-4, further including an additional logic layer including an additional logic circuit, in which the additional logic layer has a fourth surface and a fifth surface, the fourth surface is bonded to the first surface, and the fifth surface opposes the fourth surface and is bonded to the second surface.

Example 6 provides the IC device according to any one of examples 1-5, in which: the first memory cell includes a first bit line and a first word line, the second memory cell includes a second bit line and a second word line, a conductive structure connected to the first bit line and the second bit line, and the first word line is separated from the second word line by an electrical insulator.

Example 7 provides the IC device according to any one of examples 1-6, in which: the first memory cell includes a first transistor including a first electrode over a first semiconductor region; the second memory cell includes a second transistor including a second electrode over a second semiconductor region, and the first electrode is coupled to the second electrode.

Example 8 provides the IC device according to any one of examples 1-7, in which: the first memory cell or the second memory cell is a dynamic random-access memory cell, and the logic layer further includes is a SRAM cell.

Example 9 provides the IC device according to any one of examples 1-8, in which the first memory cell or the second memory cell includes a transistor and a capacitor, the capacitor is coupled to an electrode of the transistor, the electrode is over a source region or drain region of the transistor.

Example 10 provides the IC device according to any one of examples 1-9, in which: the first memory cell or the second memory cell includes a first transistor, the logic layer includes a second transistor; and a semiconductor structure of the first transistor has a different shape from a semiconductor structure of the second transistor.

Example 11 provides the IC device according to example 10, in which the semiconductor structure of the first transistor includes a first nanoribbon, the semiconductor structure of the second transistor includes a second nanoribbon, and a width of the first nanoribbon is larger than a width of the second nanoribbon.

Example 12 provides the IC device according to example 10 or 11, in which the semiconductor structure of the first transistor includes a fin, the semiconductor structure of the second transistor includes a nanoribbon.

Example 13 provides the IC device according to any one of examples 1-12, in which: the logic circuit includes a first transistor, an additional logic layer including an additional logic circuit that includes a second transistor, and a semiconductor structure of the first transistor has a different shape from a semiconductor structure of the second transistor.

Example 14 provides the IC device according to any one of examples 1-13, in which the logic circuit includes a PMOS transistor and a NMOS transistor.

Example 15 provides an IC device, including a first logic layer having a first surface; a second logic layer having a second surface; and a memory layer having a third surface, the memory layer coupled to the first logic layer and the second logic layer, in which the first surface is perpendicular to the first surface and the second surface, and the second surface is perpendicular to the third surface.

Example 16 provides the IC device according to example 15, in which the memory layer includes a bit line and a word line, the bit line is coupled to a logic circuit in the first logic layer, and the word line is coupled to a logic circuit in the second logic layer.

Example 17 provides the IC device according to example 15 or 16, in which: the memory layer is a first memory layer, the IC device further includes a second memory layer having a fourth surface, and the fourth surface is parallel to the first surface.

Example 18 provides an IC device, including a first die including a memory array and having a first surface; a second die including a memory array or a logic circuit and having a second surface; and a third die including a logic circuit and having a third surface, in which: the first die and the second die are over the third die, the first surface and the second surface are perpendicular to the third surface, the first die is coupled to the second die or third die.

Example 19 provides the IC device according to example 18, further including a fourth die over the third die, in which the fourth die is between the first die and the second die, the fourth die includes a memory array coupled to the memory array in the first die and to the logic circuit in the second die.

Example 20 provides the IC device according to example 18 or 19, further including a conductive structure over the third die, an interconnect in the first die coupled to an interconnect in the second die through the conductive structure, in which a longitudinal axis of the conductive structure is parallel to the third surface.

Example 21 provides an IC package, including the IC device any one of examples 1-20; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first memory layer comprising a first memory cell and having a first surface;
a second memory layer comprising a second memory cell and having a second surface; and
a logic layer comprising a logic circuit and having a third surface, the logic circuit coupled to the first memory cell or the second memory cell,
wherein:
the first memory layer and the second memory layer are over the third surface,
the first surface or the second surface are at an angle from the third surface, and
the angle is in a range from approximately 0 to approximately 90 degrees.

2. The IC device according to claim 1, further comprising:
an additional logic layer comprising an additional logic circuit and having a fourth surface,
wherein the additional logic layer is over the third surface, and the fourth surface is perpendicular to the first surface or the second surface.

3. The IC device according to claim 2, wherein:
the logic circuit is coupled to a bit line of the first memory cell or a bit line of the second memory cell, and
the additional logic circuit is coupled to a word line of the first memory cell or a word line of the second memory cell.

4. The IC device according to claim 2, wherein:
the logic circuit comprises a word line driver that is coupled to the first memory cell or the second memory cell, and
the additional logic circuit comprises a sense amplifier coupled to the first memory cell or the second memory cell.

5. The IC device according to claim 1, further comprising:
an additional logic layer comprising an additional logic circuit,
wherein the additional logic layer has a fourth surface and a fifth surface, the fourth surface is bonded to the first surface, and the fifth surface opposes the fourth surface and is bonded to the second surface.

6. The IC device according to claim 1, wherein:
the first memory cell comprises a first bit line and a first word line,
the second memory cell comprises a second bit line and a second word line,
a conductive structure connected to the first bit line and the second bit line, and
the first word line is separated from the second word line by an electrical insulator.

7. The IC device according to claim 1, wherein:
the first memory cell comprises a first transistor comprising a first electrode over a first semiconductor region;
the second memory cell comprises a second transistor comprising a second electrode over a second semiconductor region, and
the first electrode is coupled to the second electrode.

8. The IC device according to claim 1, wherein:
the first memory cell or the second memory cell is a dynamic random-access memory cell, and
the logic layer further comprises a static random-access memory cell.

9. The IC device according to claim 1, wherein:
the first memory cell or the second memory cell comprises a transistor and a capacitor,
the capacitor is coupled to an electrode of the transistor, and
the electrode is over a source region or drain region of the transistor.

10. The IC device according to claim 1, wherein:
the first memory cell or the second memory cell comprises a first transistor,
the logic layer comprises a second transistor, and
a semiconductor structure of the first transistor has a different shape from a semiconductor structure of the second transistor.

11. The IC device according to claim 10, wherein:
the semiconductor structure of the first transistor comprises a first nanoribbon,
the semiconductor structure of the second transistor comprises a second nanoribbon, and
a width of the first nanoribbon is larger than a width of the second nanoribbon.

12. The IC device according to claim 10, wherein the semiconductor structure of the first transistor comprises a fin, and the semiconductor structure of the second transistor comprises a nanoribbon.

13. The IC device according to claim 1, wherein:
the logic circuit includes a first transistor,
an additional logic layer comprising an additional logic circuit that includes a second transistor, and
a semiconductor structure of the first transistor has a different shape from a semiconductor structure of the second transistor.

14. The IC device according to claim 1, wherein the logic circuit comprises a P-type metal-oxide-semiconductor transistor and a N-type metal-oxide-semiconductor transistor.

15. An integrated circuit (IC) device, comprising:
a first logic layer having a first surface;
a second logic layer having a second surface; and
a memory layer having a third surface, the memory layer coupled to the first logic layer and the second logic layer,
wherein the first surface is perpendicular to the first surface and the second surface, and the second surface is perpendicular to the third surface.

16. The IC device according to claim 15, wherein:
the memory layer comprises a bit line and a word line,
the bit line is coupled to a logic circuit in the first logic layer, and
the word line is coupled to a logic circuit in the second logic layer.

17. The IC device according to claim 15, wherein:
the memory layer is a first memory layer,
the IC device further comprises a second memory layer having a fourth surface, and
the fourth surface is parallel to the first surface.

18. An integrated circuit (IC) device, comprising:
a first die comprising a memory array and having a first surface;
a second die comprising a memory array or a logic circuit and having a second surface; and
a third die comprising a logic circuit and having a third surface,
wherein:
the first die and the second die are over the third die,
the first surface and the second surface are perpendicular to the third surface, and
the first die is coupled to the second die or third die.

19. The IC device according to claim 18, further comprising:
a fourth die over the third die,
wherein the fourth die is between the first die and the second die, and the fourth die comprises a memory array coupled to the memory array in the first die and to the logic circuit in the second die.

20. The IC device according to claim 18, further comprising:
a conductive structure over the third die,
wherein an interconnect in the first die is coupled to an interconnect in the second die through the conductive structure, and a longitudinal axis of the conductive structure is parallel to the third surface.
